(19) United States
(12) Patent Application Publication
(10) Pub. No.: US 2008/0105069 A1
(43) Pub. Date: May 8, 2008

(54) Fine Stage Z Support Apparatus

(76) Inventors: Michael B. Binnard, Belmont, CA (US); Andrew J. Hazelton, Tokyo (JP); Douglas C. Watson, Tokyo (JP); Yoichi Arai, Saitama-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/666,858

(22) PCT Filed: Nov. 4, 2005
(86) PCT No.: PCT/US05/40229

§ 371 Date: Nov. 27, 2007

Related U.S. Application Data
(60) Provisional application No. 60/625,699, filed on Nov. 4, 2004.
(60) Provisional application No. 60/625,420, filed on Nov. 4, 2004.
(60) Provisional application No. 60/647,901, filed on Jan. 28, 2005.

(51) Int. Cl. A47J 43/08; B65H 1/00; F16M 11/00; H01L 21/00

(52) U.S. Cl. 74/16; 414/222.05; 248/638; 29/25.01

(57) ABSTRACT

An apparatus for supporting an object is disclosed. The apparatus includes an air bearing coupled to an air bellows. When used in a vacuum environment, the apparatus preferably includes an air bearing housing with vacuum to remove the pressurized fluid used in the air bearing.

### CROSS-REFERENCE TO RELATED APPLICATIONS

Pursuant to 35 U.S.C. § 119, this application claims the benefit of priority to U.S. Provisional Application No. 60/625,699, filed Nov. 4, 2004, U.S. Provisional Application No. 60/625,420, also filed Nov. 4, 2004, and U.S. Provisional Application No. 60/647,901, filed Jan. 28, 2005. All three provisional applications are expressly incorporated herein by reference.

### BACKGROUND

1. Technical Field

Embodiments disclosed herein relate to an apparatus for supporting an object that may require precise positioning in the vertical degrees of freedom.

2. Related Art

The need for precise positioning of an object is required in many fields of application, including applications in semiconductor manufacturing such as microlithography. As microelectronics become faster and more powerful, an ever increasing number of transistors are required to be positioned on a semiconductor chip. This necessitates closer placement of the transistors and circuits interconnecting them, which in turn requires an ever increasing accuracy and precision in the methods for laying down the circuits on the chip. Thus, there is a need for more precise positioning, and maintaining of position, of a substrate during microlithography.

Various systems have been designed to attempt to improve fine positioning and movement control of an object. These systems typically provide the ability to control the position and movement of an object in the six spatial degrees of freedom “DOF” conventionally defined as linear and rotational movement of an object within a three dimensional space as illustrated in FIG. 1.

As conventionally defined, the first DOF is linear movement parallel to a first horizontal line passing through the object's center of gravity. The first line is conventionally labeled the “X” axis, and any movement parallel to the X axis is termed “in the X direction.” The second DOF is conventionally defined as linear movement parallel to a second horizontal line passing through the object's center of gravity and normal to the first line. The second line is conventionally labeled the “Y” axis, and movement parallel to it is conventionally termed “in the Y direction.” The third DOF is conventionally defined as linear movement parallel to a vertical line—that is, one that is normal, to the first and second horizontal lines—passing through the object's center of gravity. The vertical line is conventionally labeled the “Z” axis and movement parallel to it is conventionally termed “in the Z direction.” The remaining three of the six DOF are rotational movements, one about the axis of each previously defined linear DOF. The first rotational DOF is conventionally termed “theta X” and is defined as vertical rotation about a line parallel to the X axis. The second rotational DOF is conventionally termed “theta Y” and is defined as vertical rotation about a line parallel to the Y axis. Each of theta X and theta Y is conventionally termed a “vertical” DOF. Thus, there are three vertical degrees of freedom: Z, theta X, and theta Y. The third rotational DOF is conventionally termed “theta Z” and is defined as horizontal rotation about a line parallel to the Z axis. Theta Z is conventionally termed a “horizontal” DOF. Thus, there are three horizontal degrees of freedom: X, Y, and theta Z.

Limits of physical systems often mean that precise positioning of an object may best be accomplished by actions of at least two positioning systems: a coarse and a fine positioning system. A first, or coarse, positioning system places the object in a location that is approximately the desired location. A second, or fine, positioning system has more precision but shorter linear or smaller rotational increments than the first positioning system. The second positioning system then precisely places the object in the desired location.

FIG. 2 illustrates a photolithography system 1000 for processing wafers that uses one or more two-part positioning systems to precisely position an object, such as a wafer. Photolithographic instrument 1000 generally comprises an illumination system 1002 that projects radiant energy (e.g. light) through a mask pattern (e.g., a circuit pattern for a semiconductor device) on a reticle (mask) 1006 that is supported by and scanned using a reticle stage (mask stage) 1010. Reticle stage 1010 may be supported by a frame 1032. The radiant energy may be focused through a projection optical system (lens system) 1004 supported on a frame 1026, which, in turn, may be anchored to the ground through a support 1028. Optical system 1004 may also be connected to illumination system 1002 through frames 1026, 1030,1032, and 1034. The radiant energy exposes the mask pattern onto a layer of photoresist on a wafer 1008. Wafer (object) 1008 may be supported by and scanned using a wafer stage 1036. Wafer stage 1036 may be supported by frame 1024 and connected to optical system 1004 through frames 1024 and 1026.

Wafer stage 1036 may include a lower (supporting) stage 1038 and an upper (fine) stage 1040. Lower stage 1038 may include a first positioning system (not shown, but well known in the art) that has a relatively long stroke in at least the X and Y DOF to coarsely position wafer 1008 (and fine stage 1040) relative to optical system 1004. Wafer 1008 may be further positioned relative to optical system 1004 in at least the X, Y, and theta Z (i.e., rotation in the XY plane) DOFs, as described above and illustrated in FIG. 1 by a second positioning system 1042 that may be a part of fine stage 1040. Fine stage 1040 includes a wafer chuck (holding portion) (not shown) on which wafer 1008 can be mounted for precise positioning. Mirrors (not shown) are typically mounted on fine stage 1040 and aligned with the X and Y axes. The mirrors provide reflective reference surfaces off of which laser light may be reflected to determine a precise X-Y position of fine stage 1040 using a laser interferometer system as a position detection system.

It may be desirable to position fine stage 1040 in the Z, theta X, and theta Y DOFs by one or more Z movers that position fine stage 1040. A Z positioning system will ideally immediately transfer a force to a point of fine stage 1040 and efficiently move fine stage 1040 to a desired Z position and orientation. A Z support system supports fine stage 1040 with respect to lower stage 1038 at the desired Z position and orientation. Ideally, a Z support system should not transmit any vibrations from other portions of photolithography system 1000 to wafer fine stage 1040.

One proposed solution supports and positions wafer fine stage 1040 in 6 DOF with electromagnetic voice coil motors (“VCMs”). The motion of the wafer fine stage 1040 would be entirely constrained using VCMs. VCMs, however, require relatively large amounts of power to generate a given amount of force. Further, using VCMs to counterbalance the weight of fine stage 1040 requires an even higher current, which generates even more heat that exceeds the ability of current liquid cooling systems to maintain the temperature of the coil and, due to heat transfer, objects, including air, in the vicinity. The high power requirements of VCMs can generate sufficient heat to change the index of refraction of the environment sufficiently to induce error in an interferometer system. Temperature control of the optical environment is preferably within 1° Celsius of the target temperature, and those parts near the wafer and interferometer are preferably controlled within 0.10° C. of the target temperature. Additionally, heat generation can cause expansion of fine stage 1040 leading to further errors in alignment and control.

A device to support and precisely position a fine stage is needed that minimizes deformation of the fine stage and, therefore, a workpiece mounted thereon.

### SUMMARY

As broadly described herein, embodiments of the invention include an apparatus for supporting an object.

An apparatus for supporting an object in the Z direction according to some embodiments of the invention may include an air bearing member, a vertical support member, a flexure connecting the vertical support member to the air bearing member, and a housing for pressurized gas. When the housing is filled with pressurized gas, a pressure differential acts on an area of the vertical support member to provide a desired force on an object.

An apparatus for supporting an object in the Z direction according to some embodiments of the invention may include an air bearing member having a planar bearing surface and a spherical bearing surface, a vertical support member having a bearing surface that mates with one of the planar bearing surface and the spherical bearing surface of the air bearing, a main frame connected to ground and guiding the vertical support member in the Z direction, and an air bellows mechanically connected to the vertical support member. When the air bellows is filled with a pressurized fluid, the air bellows exerts a desired force on the vertical member, a portion of which is transmitted through the air bearing member to support the object.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments consistent with the invention and together with the description, serve to explain the principles of the invention. In the drawings,

FIG. 1 illustrates a perspective view of an object in a three-dimensional coordinate system with the conventionally termed degrees of freedom labeled.

FIG. 2 illustrates a front view of a conventional photolithography system for wafer processing.

FIG. 3a illustrates a cross-sectional view of a Z support according to some embodiments of the invention supporting an object above the Z support;

FIG. 3b illustrates a cross-sectional view of the Z support illustrated in FIG. 3a supporting an object below the Z support;

FIG. 4 illustrates a cross-sectional view of a flexure according to some embodiments of the invention;

FIG. 5 illustrates a top view of the flexure illustrated in FIG. 4;

FIG. 6 illustrates a cross-sectional view of another flexure according to some embodiments of the invention;

FIG. 7 illustrates a top view of the flexure illustrated in FIG. 6;

FIG. 8 illustrates a side view of yet another flexure according to some embodiments of the invention;

FIG. 9 illustrates another side view of the flexure along line 9-9 as illustrated in FIG. 8;

FIG. 10 illustrates a cross-sectional view of a Z support according to some embodiments of the invention;

FIG. 11 illustrates a perspective view of a Z support according to some embodiments of the invention and similar to the Z support illustrated in FIG. 10;

FIG. 12 illustrates a partial cross-sectional view of another Z support according to some embodiments of the invention similar in all regards to the Z support illustrated in FIG. 10 except an air bearing member with an annular planar air bearing surface and an annular spherical air bearing surface;

FIG. 13 illustrates a partial cross-sectional view of a Z support according to some embodiments of the invention similar in all regards to the Z support illustrated in FIG. 10 except a flexure secured between an air bearing member and vertical support member;

FIG. 14 illustrates a cross-sectional view of a Z support according to some embodiments of the invention for use in a low pressure or vacuum environment;

FIG. 15 illustrates a perspective view of an air bearing pack of the Z support illustrated in FIG. 14;

FIG. 16 illustrates a cross-sectional view of the air bearing pack illustrated in FIG. 15;

FIG. 17 illustrates another cross-sectional view of the air bearing pack illustrated in FIGS. 15 and 16;

FIG. 18 illustrates a partial perspective and cross-sectional view of the main frame with vacuum guard rings of the Z support illustrated in FIG. 14;

FIG. 19 illustrates the magnetic flux and resulting force in the Z direction from current flow in an embodiment of a voice coil motor;

FIG. 20 illustrates a perspective view of a Z positioning and support device according to some embodiments of the invention for use in a low pressure or vacuum environment;

FIG. 21 illustrates a cross-sectional view of the Z positioning and support device illustrated in FIG. 20;

FIG. 22 illustrates an enlarged perspective view of the flexure illustrated in FIG. 21;

FIG. 23 illustrates a cross-sectional view of another Z positioning and support device according to some embodiments of the invention;

FIG. 24 illustrates a perspective view of yet another Z positioning and support device according to some embodiments of the invention;

FIG. 25 illustrates a partial perspective and cross-sectional view of physically connected and moving parts of the Z positioning and support device illustrated in FIG. 24;

FIG. 26 illustrates a partial perspective and cross-sectional view of the flexure illustrated in FIG. 25;

FIG. 27 illustrates a cross-sectional view of yet another Z positioning and support device according to some embodiments of the invention;

FIG. 28 illustrates an exploded, perspective view of a fine stage assembly with three Z positioning and support devices as illustrated in FIG. 24;

FIG. 29 illustrates a perspective view of the fine stage illustrated in FIG. 28;

FIG. 30 illustrates an exploded, perspective view of a table of the fine stage illustrated in FIG. 28;

FIG. 31 illustrates another exploded, perspective view of table illustrated in FIG. 28;

FIG. 32 illustrates an exploded, perspective view of another embodiment of a fine stage table;

FIG. 33 illustrates another perspective view of the fine stage illustrated in FIG. 28;

FIG. 34 illustrates a simplified bottom view of a lower stage section and portions of the X and Y moving assemblies (positioning system) of the fine stage illustrated in FIG. 33;

FIG. 35 illustrates an extreme ultra-violet (“EUV”) lithography system according to some embodiments of the invention;

FIG. 36 is a flow diagram of a process of fabricating semiconductor devices; and

FIG. 37 is a detailed flow diagram of the above-mentioned step 504 in the case of fabricating semiconductor devices.

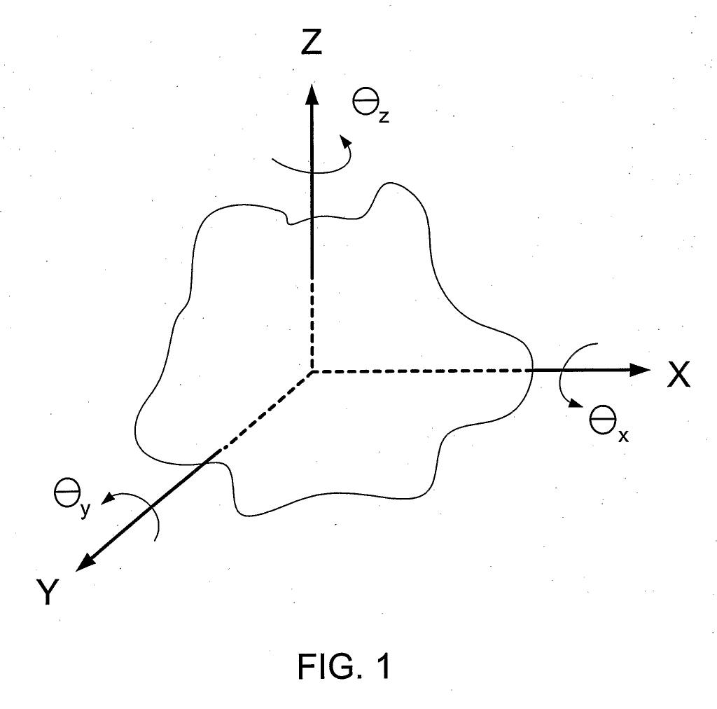

### DESCRIPTION OF EMBODIMENTS

Reference will now be made in detail to exemplary embodiments consistent with the invention, which are illustrated in the accompanying drawings. Wherever possible, the same reference numbers will be used throughout the drawings to refer to the same or like parts.

A Z support according to some embodiments of the invention includes an air bearing member (generally referred to as 44 in the text and depicted in the Figs. as specific embodiments labeled 44-1, 44-2, etc.), a vertical support member (generally referred to as 46 in the text and depicted in the Figs. as specific embodiments labeled 46-1, 46-2, etc.), a main frame connected directly or indirectly to ground, and a housing (generally referred to as 50 in the text and depicted in the Figs. as specific embodiments labeled 50-1, 50-2, etc.) connected directly or indirectly to ground, wherein when the housing is filled with pressurized fluid (generally referred to as 52 in the text and labeled in the Figs. as 52-1 for positive pressure relative to ambient and 52-2 for negative pressure relative to ambient) a desired force is exerted on vertical support member to support at least the object with respect to ground.

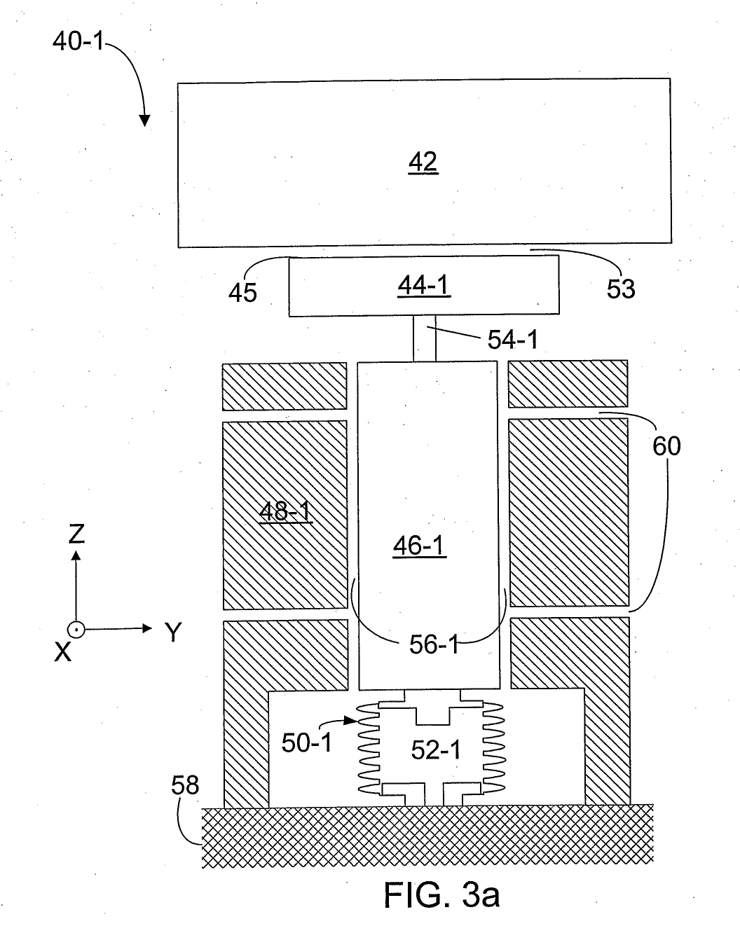

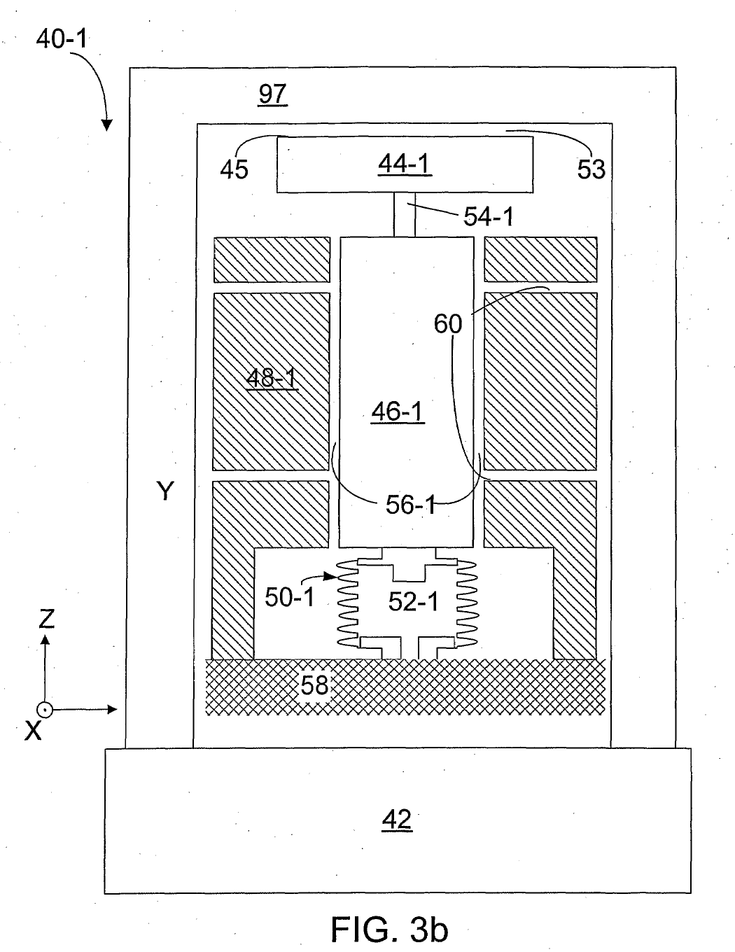

A Z support 40-1 for supporting an object 42 in the “Z” direction according to some embodiments of the invention is illustrated in FIGS. 3a & b. FIG. 3a illustrates Z support 40-1 located below object 42. FIG. 3b illustrates Z support 40-1 located above object 42. In some embodiments, including the one illustrated in FIGS. 3a & b, Z support 40-1 includes a disc-shaped air bearing member 44 to permit supported object 42 to freely move in the X, Y, and theta Z DOFs with respect to Z support 40-1. A bearing surface 45 of air bearing member 44 forms one of the mating bearing surfaces for an air bearing 53 between air bearing member 44 and supported object 42 (FIG. 3a) or a projection 97 rigidly attached to object 42 (FIG. 3b).

Air bearing member 44 may be one of at least two general types, which often provide a typical flying height of 3-20 microns. A first type is typically referred to as a porous air bearing. A portion of such an air bearing member is typically made of carbon or a ceramic and forms at least a portion that supplies pressurized air to air bearing surface 45 in a substantially uniform manner. Porous air bearings are available from Devitt Machinery Co. in Aston, Pa. (see website at www.newwayairbearings.com). A second type is typically referred to as an orifice air bearing. An orifice air bearing typically has a plurality (for example 3 or 4) of small orifices spaced apart on air bearing surface 45 that supply pressurized air to air bearing 53.

For both types of air bearing structures described above, it may be desirable to supply vacuum to another portion of air bearing surface 45 to create additional pre-load force for the air bearing. Increasing the pre-load force increases the stiffness of air bearing 53, which may be desirable.

It should also be noted that the fluid forming air bearing 53 may be supplied from the mating surface of bearing surface 45, which as illustrated in FIG. 3, would be a bottom surface of object 42.

in some embodiments, including the one illustrated in FIGS. 3a & b, air bearing member 44-1 may be mechanically connected to vertical support member 46 by a flexure (generally referred to in the text as 54 and depicted in the Figs. as specific embodiments labeled 54-1, 54-2, etc.) that acts as a compliant spring in the theta X and theta Y degrees of freedom. Flexure 54 may prevent over constraint of object 42 during tilting (rotation) of the object in the theta X and theta Y degrees of freedom. Flexure 54 may have any size, shape, and design that provides rigid support in the Z direction (high vertical stiffness) and flexibility about the X and Y axes (low bending stiffness), such that object 42 may rotate through small angles about the X and Y axes with little resistance. The elastic deformation of at least a portion of flexure 54, as the object moves in the theta X and or theta Y degrees of freedom, allows a small range of motion. Flexure 54 may be made of a high yield strength material, e.g., stainless steel, beryllium copper, or maraging steel. The amount of deformation in response to expected forces and moments during normal use is determined by standard stress/strain calculations given the chosen material and the dimensions of flexure 54. In some embodiments, including the one illustrated in FIGS. 3a & b, flexure 54-1 is a cylinder of smaller diameter than either disc-shaped air bearing member 44-1 or hollow, cylindrical shaft 46-1.

In some embodiments, including the one illustrated in FIGS. 3a & b, vertical support member 46 is a hollow, cylindrical shaft 46-1. In some embodiments, the horizontal cross section of vertical support member 46 is not round, nor constant in size or shape. Vertical support member 46 may be guided in the Z direction and may allow rotation about the Z axis by a bushing (generally referred to in the text as 56 as depicted in the Figs. as specific embodiments labeled 56-1, etc.). In some embodiments, bushing 56 may be an air bushing 56-1 formed between the outer wall of vertical support member 46 and a surface of main frame 48-1 forming a through-hole in which at least a portion of vertical support member 46 is located. Air bushings may be a separately supplied component, such as those sold as radial air bearings by Devitt Machinery Co. (www.newwavairbearings.com). In some embodiments, air bushing 56-1 may be supplied with pressurized fluid through pathways 60 in main frame 48 connected to a supply of pressurized fluid (not shown). Main frame 48 may take any desired shape or size. Main frame 48 may be directly or indirectly connected to ground 58. In some embodiments, including the one illustrated in FIGS. 3a & b, main frame 48-1 has a cylindrical bushing surface.

In some embodiments, including the one illustrated in FIGS. 3a & b, housing 50 for pressurized gas is an air bellows 50-1. In some embodiments, air bellows 50-1 includes a rigid top connected to vertical support member 46, a rigid bottom connected to ground 58, and a flexible walled portion connected to the top and bottom. In some embodiments, air bellows 50-1 has low axial stiffness. An example of an air bellows 50-1 with low axial stiffness is an electroformed nickel bellows of the type manufactured by Servometer Corporation of Cedar Grove, N.J. In some embodiments, air bellows 50-1 has a higher axial stiffness, such as, for example, a welded bellows. In some embodiments, air bellows 50-1 may be filled to a pressure calculated to supply a desired force on an object and then sealed or otherwise closed. Air bellows 50-1 may include a gas port for a supply of constant pressure gas (not shown). In some embodiments, the gas port may be located in the rigid bottom of air bellows 50-1. In some embodiments, pressurized gas 52-1 acts on an area of air bellows 50-1 to provide a desired force on vertical support member 46.

Embodiments of a Z support 40 according to the invention using an air bellows 50-1 connected to a vertical support member 46 that is constrained to movement only in the Z direction have a benefit over a Z support that may connect an air bellows directly to fine stage 1040. If an air bellows moves only in the Z direction, it may be accurately modeled as a linear spring. When an air bellows is directly attached to fine stage 1040 to support the weight, any motion in the X, Y, theta X, theta Y, or theta Z degrees of freedom of fine stage 1040 corresponding move the top of the air bellows with respect to the bottom changes the stiffness of the air bellows undesirably and negatively affects the fine stage positioning performance. By eliminating motion of the top of the air bellows with respect to the bottom in all but the Z degree of freedom, the lateral stiffness of the air bellows does not need to be modeled, which makes the air bellows easier to design, and the vertical stiffness may be constant and linear.

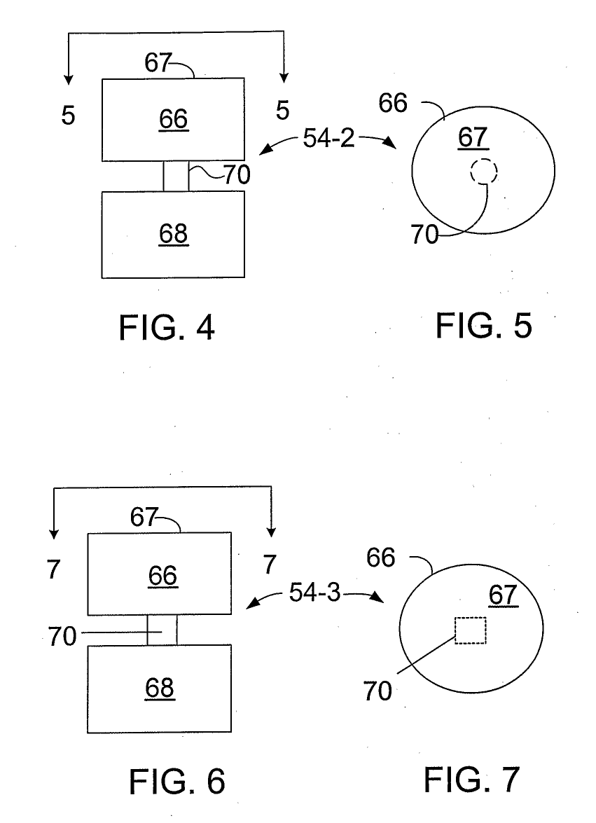

FIGS. 4-9 illustrate cross-sectional and top views of exemplary embodiments of flexure 54. In some embodiments, including flexures 54-2 and 54-3 illustrated in FIGS. 4-7, a flexure 54 may have an upper portion 66, a lower portion 68, and a waist 70. A top surface 67 of upper portion 66 may be connected to air bearing member 44. In some embodiments, including flexures 54-2 and 54-3 illustrated in FIGS. 4-7, upper portion 66 and lower portion 68 may be of equal circular cross section. In some embodiments, waist 70 is concentrically located with respect to upper portion 66 and lower portion 68. In some embodiments, only waist 70 elastically deforms about at least one of the X and Y axes, allowing upper portion 66 to rotate about the X and/or Y axis with respect to lower portion 68. Waist 70 may be of any desired cross sectional shape, and typically its cross-section is circular as illustrated in FIG. 5, or square as illustrated in FIG. 7.

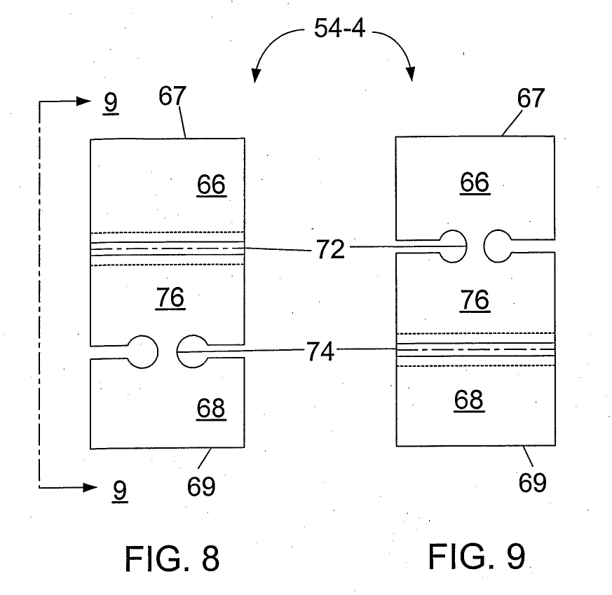

In some embodiments of flexure 54, like flexure 54-4 illustrated in FIGS. 8 & 9, two horizontal and perpendicular, but vertically stacked, flexing members 72 and 74 may provide the flexibility. Each flexing member has a low bending stiffness in one of the X and Y degrees of freedom and a higher bending stiffness in the other of the X and Y degrees of freedom. Each flexing member may have its own center of rotation. In some embodiments of flexure 54, like flexure 54-4 illustrated in FIGS. 8 & 9, flexing members 72 and 74 are vertically separated, but are still horizontal and perpendicular to each other. In some embodiments, flexure 54-4 may have an upper portion 66, a lower portion 68, and an intermediate portion 76. In some embodiments, flexing member 72 joins upper portion 66 and intermediate portion 76. In some embodiments, flexing member 74 joins lower portion 68 and intermediate portion 76. Upper portion 66, intermediate portion 76, and lower portion 68 may have any desired cross-sectional shape. Typical cross-sectional shapes include circular or square for equal bending stiffness in the theta X and theta Y directions, or rectangular for different bending stiffnesses.

Such a “crossed blade” design, as illustrated in FIGS. 8 & 9, may offer the benefit of increased axial stiffness relative to a flexure design having a single waist. However, such a “crossed blade” design may have different centers of rotation for the theta X and theta Y motion.

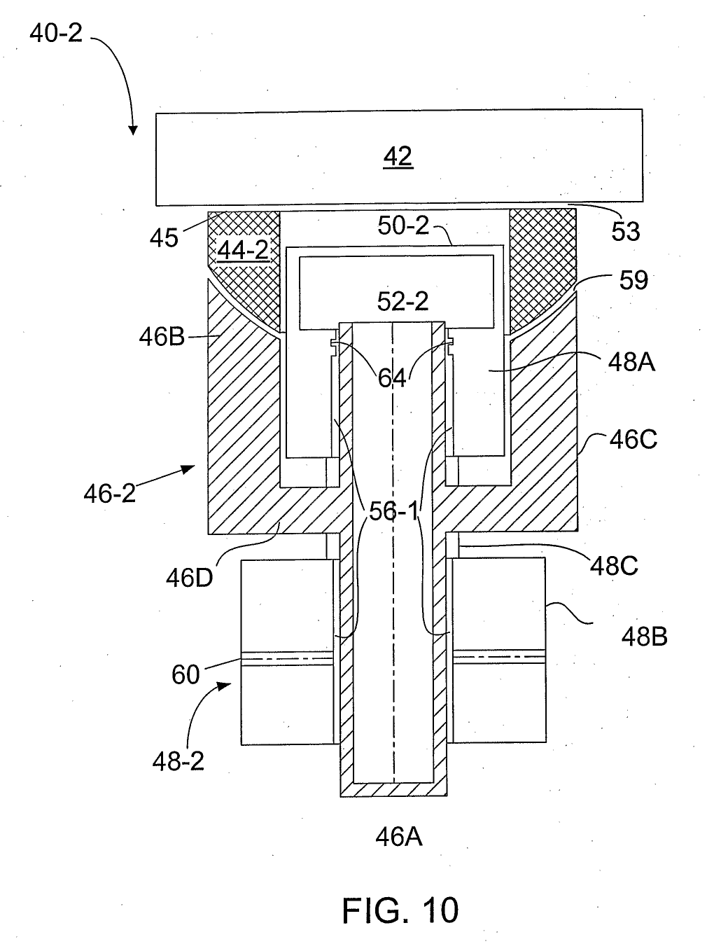

Another embodiment of a Z support 40-2 according to some embodiments of the invention is illustrated in FIG. 10. Components in this embodiment that are in common with those in the embodiment illustrated in FIGS. 3a & b will not be discussed again. In some embodiments, including the one illustrated in FIG. 10, air bearing member 44-2 may be an annulus. In some embodiments, including the one illustrated in FIG. 10, air bearing member 44-2 is supported by a spherical air bearing 59 between its lower bearing surface and an upper bearing surface of vertical support member 46-2. In some embodiments, air bearing member 44-2 has a spherically shaped lower bearing surface. In some embodiments, including the one illustrated in FIG. 10, air bearing member 44-2 has a convex spherical bearing surface. In some embodiments, vertical support member 46-2 has a mating spherical annular surface that forms the lower boundary of air bearing 59 between vertical support member 46-2 and air bearing member 44-2. Such mating spherical surfaces may allow air bearing member 44 to rotate with object 42 about the X and Y axes without transmitting such rotations to vertical support member 46-2.

Of course, it is possible to exchange the positions of air bearings 53 and 59. In other words, the spherical bearing could be located above the planar bearing. If spherical bearing 59 is located above the planar bearing, object 42 may have a projection 97 (not shown) with a bottom, spherical bearing surface to mate with the spherical bearing surface of air bearing member 44-2 or 44-3 and form one of the two boundary surfaces for air bearing 59. And, again, as previously described, the fluid forming air bearings 53 and 59 may be supplied from either bearing surface. With regard to spherical bearing 59, then, in some embodiments, fluid is supplied to spherical bearing 59 from the mating spherical surface of vertical support member 46. In some embodiments, fluid for both air bearings 53 and 59 may be supplied from vertical support member 46 in conjunction with appropriate channels in spherical air bearing member 44-2 or 44-3.

In some embodiments, vertical support member 46-2 may include a hollow, cylindrical body 46A with an open end in fluid communication with the pressurized gas 52 within housing 50. In some embodiments, including the one illustrated in FIG. 10, housing 50 may be a structure consisting of rigid walls 50-2 and has an opening in a bottom wall through which a portion of vertical support member 46-2 may fit and enter an enclosed volume of structure consisting of rigid walls 50-2. In some embodiments, including the one illustrated in FIG. 10, pressurized gas 52 is maintained at a negative pressure 52-2 down to and including an absolute vacuum.

Using vacuum to support the weight of object 42 may have the benefit of not having a compressibility-related stiffness in the same way as pressurized air. In the embodiments shown in FIGS. 3a & b, vertical motion of object 42 and vertical support member 46 changes the volume of the air bellows 50-1. If the amount of pressurized air therein is substantially constant, such vertical motion creates a change in the support force, due to the relationship of volume and pressure in the ideal gas law, pV=nRT. In this way, the air acts as an additional stiffness between ground 58 and object 42. Using vacuum in a structure consisting of rigid walls 50-2 as shown in FIG. 10 can reduce or eliminate the air stiffness. In this case, it may be desirable to prevent air from entering structure consisting of rigid walls 50-2 through an opening remaining around the portion of vertical support member 46-2 that enters the enclosed volume of structure consisting of rigid walls 50-2. One such way to prevent air from doing so may include a “vacuum guard ring” located in main frame 48-2 as discussed below.

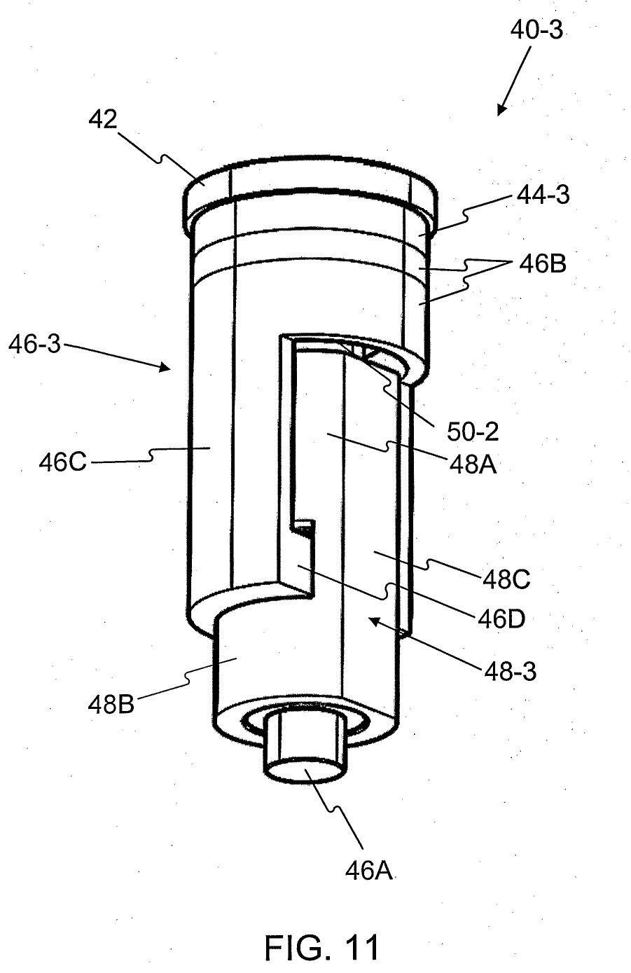

In some embodiments, and as illustrated best in FIG. 11, vertical support member 46-2 and 46-3 both include an upper annular, cylindrical portion 46B, having diameters approximately matching those of an annular air bearing member 44-2 or 44-3, respectively, a hollow semi-cylindrical portion 46C having the same inner and outer diameters of portion 46B and concentric with a hollow, cylindrical portion 46A of a second, smaller diameter, which extends up through the cylindrical space created by the inner diameter of portions 46B and 46C. In some embodiments, including the one illustrated in FIGS. 10 & 11, hollow, cylindrical portion 46A is connected to hollow, semi-cylindrical portion 46C by a horizontal semi-disc-like portion 46D. Hollow, cylindrical portion 46A may be closed on the bottom end and open on the top.

In some embodiments, including Z supports 40-2 and 40-3 illustrated in FIGS. 10 & 11, main frames 48-2 and 48-3 may both include two or more co-linear journals 48A and 48B around cylindrical portion 46C of vertical support member 46-2 or 46-3, respectively, connected by a vertical, bridging portion 48C (best illustrated in FIG. 11).

In some embodiments, main frame 48 includes one or more “vacuum guard rings” 64 (best illustrated in FIG. 10) to remove any positively pressurized fluid escaping from air bushing 56-1 and reduce the chances that positively pressurized fluid will flow into structure consisting of rigid walls 50-2 filled with negatively pressurized air 52-2. It is also possible to have one or more vacuum guard rings on the vertical support member. A vacuum guard ring 64 may be one or more recesses that are connected to a vacuum pump (not illustrated) or other suction source via pathways (not illustrated). In some embodiments, the clearance between vertical support member 46 and the wall of main frame 48 adjacent to vacuum guard ring 64 is on the order of 2-3 microns. In some embodiments, including the one illustrated in FIG. 10, structure consisting of rigid walls 50-2 may be an integral part of main frame 48-2.

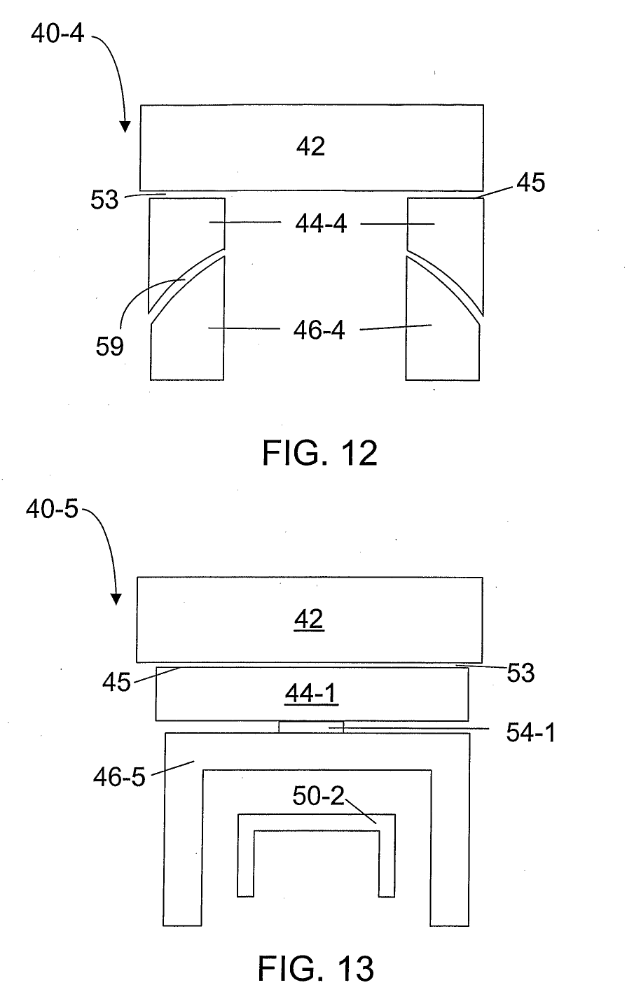

As illustrated in FIG. 12, in some embodiments, Z support 40-4 may have an air bearing member 44-4 shaped as an annulus with a planar upper bearing surface and a concave, spherical, lower bearing surface. In some embodiments, also illustrated in FIG. 12, vertical support member 46-4 may include a convex spherical upper bearing surface mating with a lower bearing surface of air bearing member 44-4. In some embodiments, including Z support 40-5 partially illustrated in FIG. 13, vertical support member 46-5 may be designed with a disc-shaped end cap to connect to a flexure 54-1, in effect, enclosing structure consisting of rigid walls 50-2. In other words, the use of a particular air bearing member 44 or housing 50 does not necessarily dictate the method of allowing air bearing member 44 to rotate with object 42, as vertical support member 46 may be designed to accommodate variations in the desired method.

A spherical air bearing (e.g., air bearing member 44-2, 44-3, and 44-4) may have a lower stiffness in the theta X and theta Y degrees of freedom than a flexure. A spherical air bearing may have lower vertical stiffness than a flexure as well. In general, spherical air bearings are more difficult and, therefore, more expensive to manufacture than flexures.

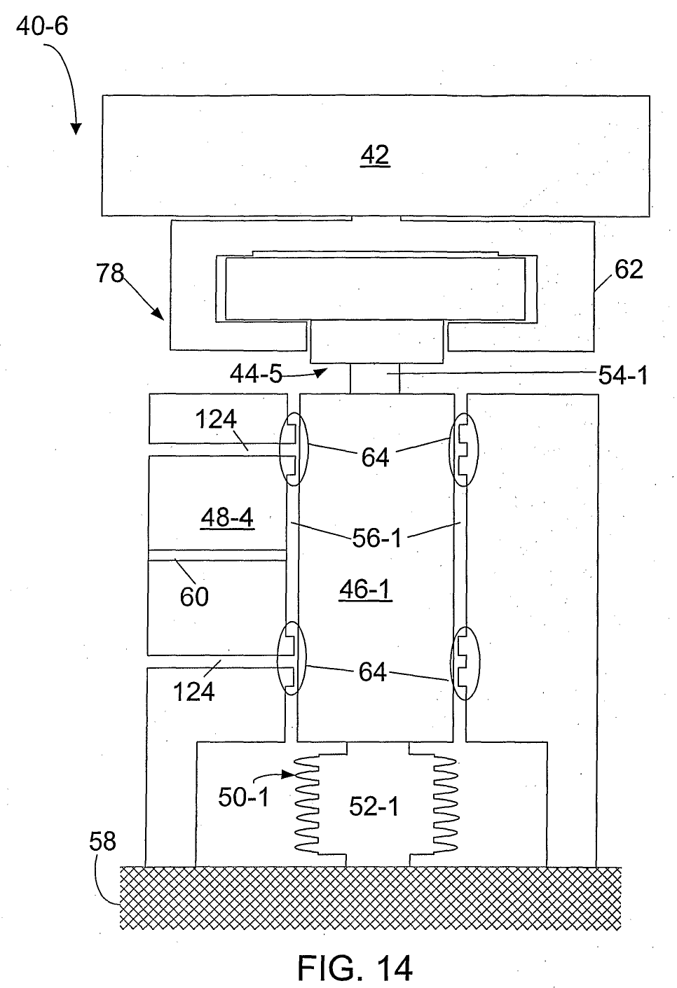

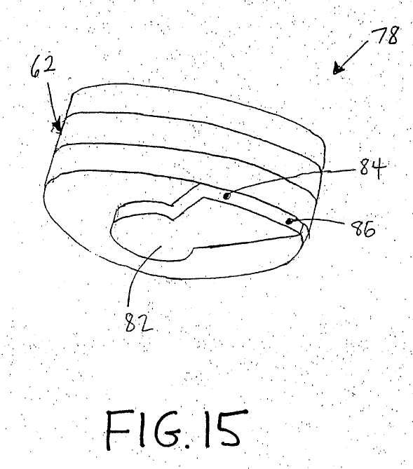

In vacuum or low pressure environments, it may be desirable to prevent the fluid used in bearings or bushings from escaping to the surrounding environment. The embodiment of Z support 40-6 illustrated in FIG. 14 is similar to Z support 40-1 discussed earlier, but also includes structures useful to reduce the flow of positively pressurized fluid to the surrounding low pressure environment: air bearing housing 62, vacuum guard rings 64, and vacuum pathways 124.

In some embodiments, an air bearing housing 62 may nearly envelop air bearing member 44-5. Air bearing housing 62 may be rigidly attached to object 42. In some embodiments, air bearing pack 78 includes air bearing housing 62 and air bearing member 44-5. As seen in FIG. 15, in some embodiments, air bearing pack 78 comprises a disc-shaped air bearing housing 62 through which a key hole-shaped portion of port block 82 may protrude from a center circular hole in air bearing housing 62. In some embodiments, port block 82 has two ports. Port 84 may be connected to pressurized air, and port 86 may be connected to vacuum.

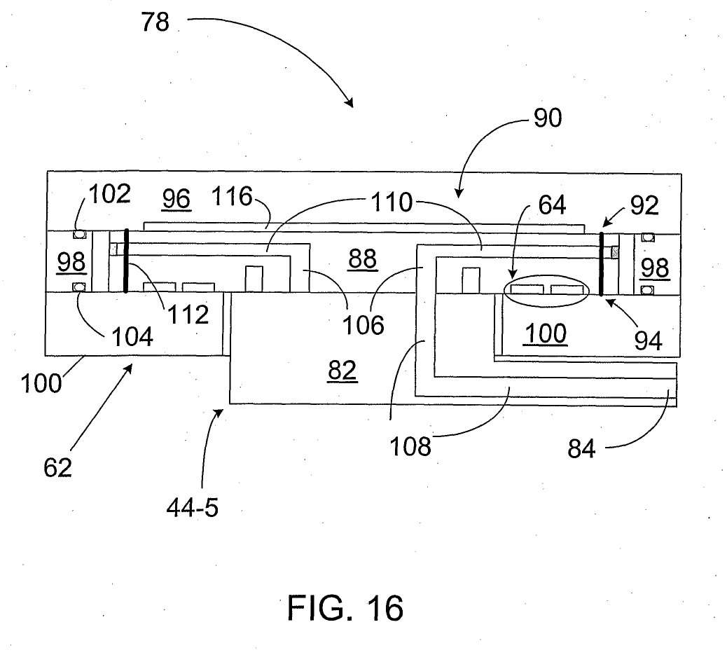

FIG. 16 illustrates a vertical cross section of air bearing pack 78 through pressurized fluid port 84. As illustrated in FIGS. 14, 16, and 17, in some embodiments, air bearing member 44-5 includes a disc-shaped, “orifice” type bearing member 88 and port block 82. As detailed below, in some embodiments, port block 82 channels pressurized fluid from port 84 to pathways 90 within bearing member 88. In some embodiments, the pressurized fluid exits bearing member 88, forming at least static air bearings 92 and 94 between bearing member 88 and air bearing housing 62.

As seen best in FIG. 16, in some embodiments, air bearing housing 62 comprises a top disc 96 that may be directly attached to object 42 (not shown). In some embodiments, air bearing housing 62 also comprises a first ring 98 and a second ring 100 with a smaller inner diameter than ring 98, for convenience of assembly of air bearing pack 78. In some embodiments, ring 98 has an inner diameter sized larger than the outer diameter of bearing member 88, to allow a desired amount of motion in the X or Y directions between ring 98 and bearing member 88 and, therefore, a desired range of motion in the X or Y directions between object 42 and Z support 40-6. In some embodiments, ring 100 and port block 82 may have a similar difference in inner and outer diameters to allow the same range of desired motion in the X and Y directions between the two parts. In some embodiments, ring 98 has two circular grooves 102 and 104. “O-rings,” as are commonly known in the art, are compressed between groove 102 or 104 and either disc 96 or ring 100, providing an air-tight seal between ring 98 and disc 96 or ring 100. Alternately, grooves 102 and 104 could be present in disc 96 and ring 100 respectively. O-rings are unnecessary if alternate means to produce an airtight housing are used, or if the amount of escaping fluid does not affect any process performed on the object sufficiently to require a reduction of fluid released to the environment of the object. Air bearing housing 62 need not be a three part construction. The illustrated three part construction of air bearing housing 62 in FIGS. 15-17 may be used for manufacturing ease and dimensional control and consistency.

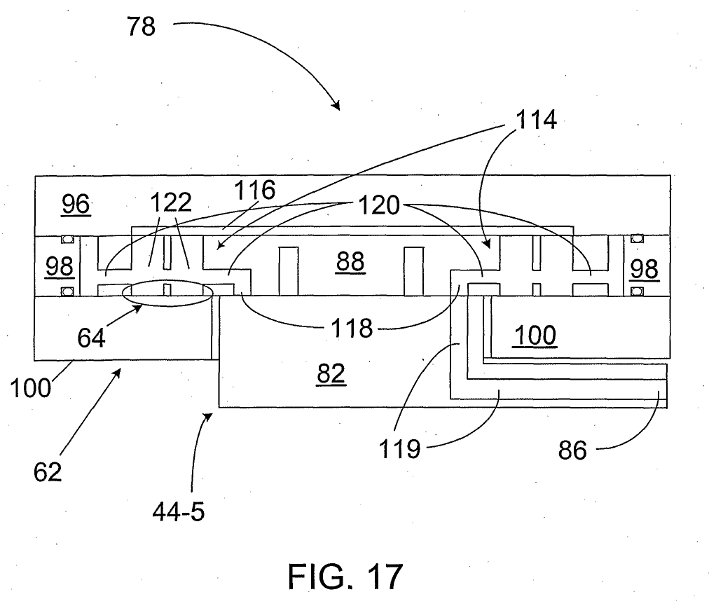

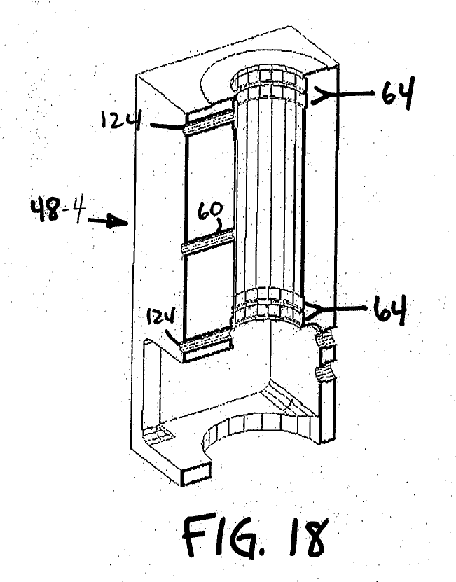

In some embodiments, pressurized fluid pathways 90 direct pressurized air from port 84 to air bearings 92 and 94. In some embodiments, pathways 90 are cylindrical holes created by drilling during manufacture that are then plugged as necessary. See, for example, the visible plugs at the circumference of bearing member 88 in FIG. 17. An annular, cylindrical recess 106 connects the single pathway 108 from port block 82 to all radial cylindrical holes 110. Smaller diameter holes 112 that create the supply orifices for air bearings 92 and 94 are in fluid communication with the radial cylindrical holes 110.

As seen best in FIG. 17, which illustrates a vertical cross section of air bearing pack 78 through vacuum port 86 of port block 82, air bearing pack 78 may include vacuum pathways 114 to reduce the pressurized fluid escaping from air bearing housing 62. In some embodiments, disc 96 has a cylindrical recess 116 in its lower face. In some embodiments, when bearing member 88 is assembled within air bearing housing 62, recess 116 and bearing member 88 create a reservoir for fluid coming from at least air bearings 92. In some embodiments, bearing member 88 also has two concentric annular recesses on its lower face, which function as vacuum guard rings 64 when connected to vacuum pathways 114. In some embodiments, vacuum guard rings 64 are in the upper face of ring 100. In some embodiments, within bearing member 88, an annular, cylindrical recess 118 connects pathway 119 from port block 82 to all radial cylindrical holes 120. Vertical through holes 122, as illustrated in FIG. 17, are in fluid communication with vacuum guard rings 64 and the cylindrical space formed by recess 116. In some embodiments, thus, pressurized fluid provided by pathways 90 is mostly removed by vacuum along pathways 114.

A very small and tightly-toleranced vertical clearance may be provided between the inner most annular area of upper face of ring 100 and the corresponding radius of bearing member 88. In some embodiments, when pressurized fluid is supplied to bearing member 88, the clearance is nominally 5 microns.

In some embodiments, the vacuum is not used for “preloading,” but to prevent the pressurized fluid from escaping into the environment around the object. In some embodiments, including the one illustrated in FIGS. 14-17, preloading is unnecessary because of the opposing static air bearings 92 and 94.

As illustrated in FIGS. 14 and 18, in some embodiments, main frame 48-4 includes vacuum guard rings 64 near the top and bottom of the continuous axial segments around vertical support member 46-1. As previously described, vacuum guard rings 64 prevent the positively pressurized fluid from escaping into the environment around the object when connected to vacuum (not shown) through vacuum pathways 124.

While only FIG. 3b illustrates an embodiment of a Z support according to the invention supporting an object below the Z support, each of the depicted embodiments may also be placed above the object they are to support in a similar manner sometime requiring a projection 97 with a bearing surface (to mate with a bearing surface of air member 44. The size, shape, and design of projection 97 may vary according to the physical requirements of object 42 and Z support 40.

By supporting the weight of an object with an embodiment of the above described Z support, a Z support and positioning system may successfully use VCMs as actuators in the Z direction without significantly changing the temperature of the surrounding environment. Other types of actuators may also be used in conjunction with Z support 40.

Using one or more air bellows to support the weight of fine stage 1040 creates a coupling between fine stage 1040 and coarse stage 1038, as previously described as a spring. This coupling transmits unwanted vibrations and disturbances to fine stage 1040. This effect may be compensated for, however, by providing a corrective force to fine stage 1040 with a Z mover, in some embodiments, a VCM.

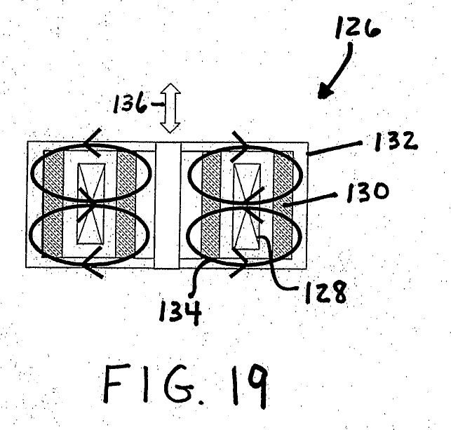

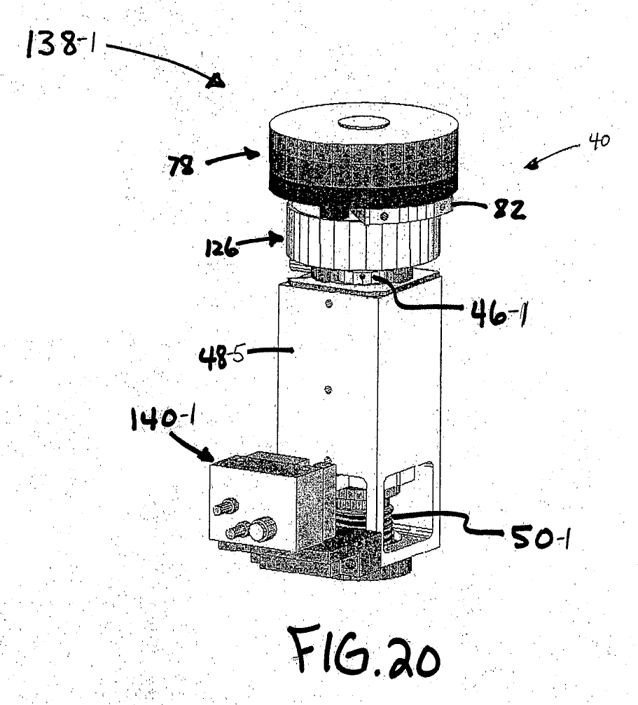

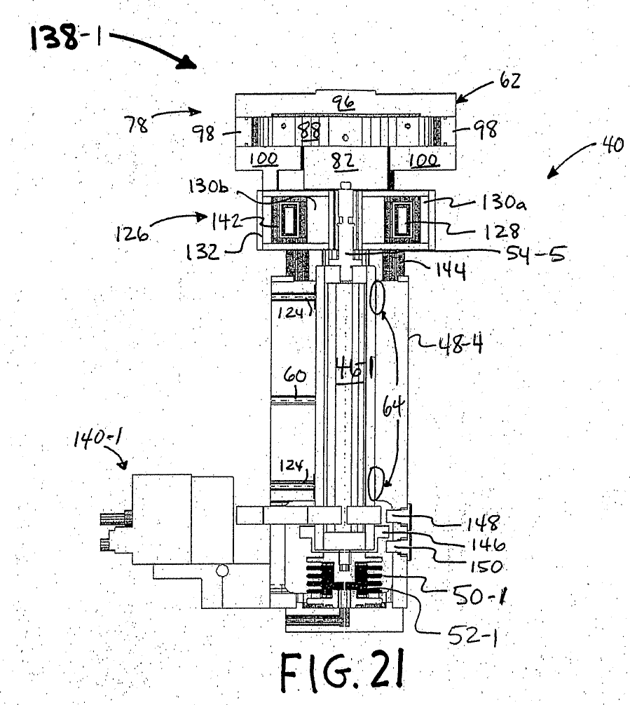

FIG. 19 illustrates the resulting magnetic flux and Z driving force of an embodiment of a commonly available VCM. A common supplier is BEI Technologies, Inc. In general, a VCM 126 uses magnets and an armature coil to provide the force necessary to raise or lower the object with respect to the reference surface, here ground 58. Typically, a coil 128 is rigidly mounted with respect to the reference surface and one or more permanent magnets 130 are mounted to a VCM housing 132. However, it is permissible to reverse the mountings, such that permanent magnets 130 are rigidly mounted to the reference surface and armature coil 128 mounts to the movable part (with respect to the reference surface). When current runs through coil 128, the resulting magnetic flux may be depicted by ovals 134. The forces generated move permanent magnets 130 and housing 132 vertically as illustrated by arrow 136, depending on the direction of the current through armature coil 128.

Yet another aspect of the present invention is a system for precisely positioning and supporting an object in the Z direction. A system according to some embodiments of the invention provides a fast servo response within a desired range of Z movement using a Z support 40 and an actuator rigidly connected to the object to be positioned. It also may provide low Z transmissibility by linearization of and compensation of stiffness of an air bellows by utilizing an actuator, control program, and a sensor installed in this system.

In some embodiments, a Z support and positioning system may apply a Z support force at a different location on the object than a Z actuation force. If an error occurs in the force applied to support the weight of the object and the Z actuator supplies a force to correct the position of the object, the non-coincident points of application of the two forces may deform the object. In applications to fine stage support and positioning, deformations that would be acceptable in some situations often cause unacceptable yield loss in a lithography process. It may be desirable to minimize the distance between points of application of the support force and the positioning force. In embodiments according to the invention that use a VCM to move the supported object into the correct position, a concentric arrangement of a Z support 40 and VCM can result in a common point of application of the net force to the object without deforming the object.

FIG. 20 illustrates a Z support and positioning device 138-1 according to some embodiments of the invention. In some embodiments, Z support and positioning device 138-1 includes a Z support 40 and a VCM 126, a standard component as described above. Some embodiments, including Z support and positioning device 138-1 illustrated in FIG. 20, also include a Z position measuring device (generally referred to in the text as 140 and labeled in the Figs. as specific embodiments 140-1, etc.) to measure the distance in the Z direction that vertical support member 46 has moved.

Z support and positioning device 138-1, illustrated in FIG. 20, incorporates an embodiment of a Z support 40 as illustrated in FIGS. 14-18, modified to accommodate a co-linear placement of a VCM 126 and an encoder 140-1. Accordingly, the embodiment illustrated in FIG. 20 includes an air bearing pack 78, a flexure 54 (not visible here, but illustrated in FIG. 21), a hollow, cylindrical shaft 46-1, a main frame 48, an air bellows 50-1, and positively pressurized gas 52-1 (not shown). Only the modified components will be discussed in detail.

Referring to FIG. 21, a cross-sectional view of Z support and positioning device 138-1 as illustrated in FIG. 20, more detail and certain subassemblies may be seen. In some embodiments, air bearing housing 62 is rigidly attached to VCM housing 132 of VCM 126. In some embodiments, VCM housing 132 circumferentially encloses permanent magnets 130a and 130b, as well as armature coil 128 and liquid cooling can 142. In some embodiments, VCM armature coil 128 and liquid cooling can 142 are rigidly attached by mounting 144 to main frame 48-4. Accordingly, in some embodiments, including the one illustrated in FIGS. 20 and 21, permanent magnets 130a and 130b of VCM 126 are rigidly connected to object 42.

In some embodiments, including the one illustrated in FIGS. 20 and 21, flexure 54-5 connects port block 82 and vertical support member 46-1 and is disposed within a through-hole defined by VCM housing 132.

In some embodiments, protrusion 146 on vertical support member 46-1 in conjunction with protrusions 148 and 150 on main frame 48-4 act to prevent excessive movement of vertical support member 46-1 in the Z direction. In some embodiments, these vertical motions are intended to be small, particularly if the particular application is for positioning a fine stage 1040 of an auto-focus apparatus (wafer stage 1036), in contrast to coarse stage 1038. In some embodiments, the maximum clearance between protrusion 146 and either protrusion 148 or 150 is in the range of about 0.3 mm to about 3.0 mm.

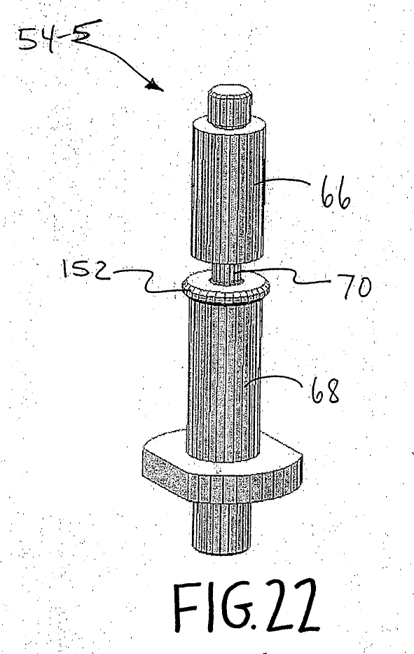

FIG. 22 illustrates an enlarged view of a flexure 54-5 according to some embodiments of the invention. In some embodiments, flexure 54-5 comprises an upper portion 66 of about 6 mm in diameter, a lower portion 68 of about 6 mm in diameter, a waist 70 of from about 1 to about 2 mm, and an annular projection 152 with a diameter larger than that of either waist 70 or lower portion 68. In some embodiments, upper portion 66, waist 70, and lower portion 68 each comprise a cylinder. In some embodiments, upper portion 66 and lower portion 68 are of similar length.

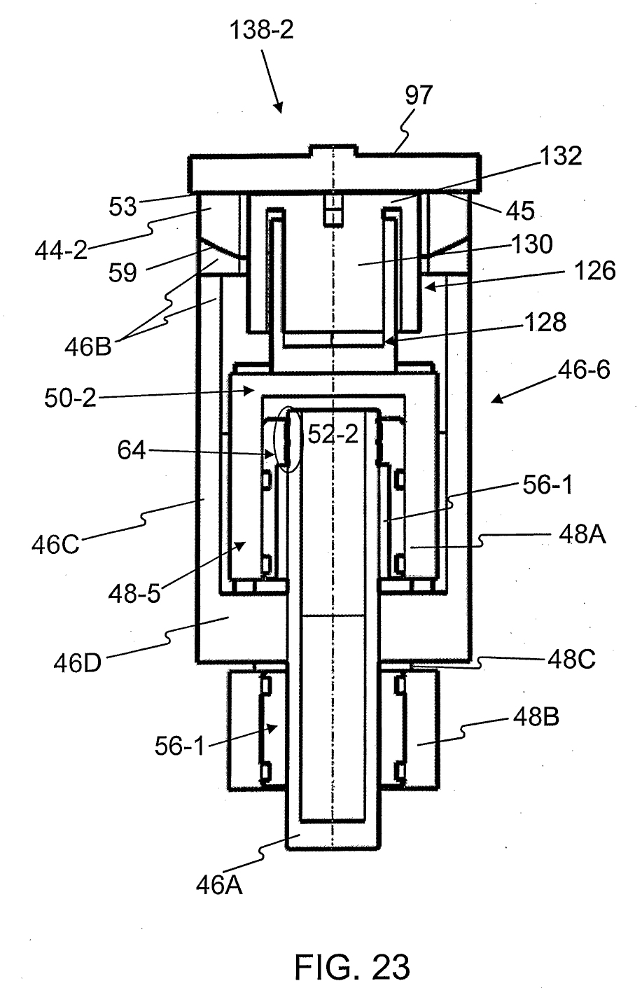

In some embodiments, including the one illustrated in FIGS. 21 and 22, flexure 54-5 is adapted to provide support in the Z direction and a small range of motion to its upper portion 66, port block 82, and bearing member 88, with respect to its lower portion 68 in the theta X and theta Y directions to match any theta X or theta Y DOF motion of object 42 and, therefore, rigidly connected air bearing housing 62, VCM housing 132, and VCM permanent magnets 130a and 130b. In some embodiments, including the one illustrated in FIG. 23, flexure 54-5 may have one center of rotation about which the elastic deformation occurs. In some embodiments, this center of rotation coincides with the center of VCM 126. The center of VCM 126 as used herein refers to the point about which the magnet rotates about the X or Y axes that maximizes its possible angular range of rotation before contacting the coil. It may or may not be the geometric center of VCM 126. Having the same center of rotation for both theta X and theta Y motion may allow for greater efficiency of the positioning means, such as for example a VCM.

In some embodiments including the one illustrated in FIGS. 20, 21, and 22, flexure 54-5 also comprises an annular projection 152 below its “waist” 70. Annular projection 152 functions as part of a hard stop for the lateral (XY) motion of the object when any part of annular projection 152 comes into contact with the inner cylindrical surface of VCM housing 132. In some embodiments, the gap between annular projection 158 and inner cylindrical surface of VCM housing 132, when assembled, is about 1 mm.

In some embodiments, the VCM current (current through armature coil 128) is controlled with a PID controller or some equivalent advanced controller that is commonly known, and need not be specifically described. A signal representing a desired position in the Z direction is sent to the controller and the current is adjusted accordingly, applying force on permanent magnets 130a and 130b in the Z direction with respect to armature coil 128. Due to the rigid connection between the object 42 and the permanent magnets 130a and 130b, the force is very quickly transferred to object 42, and it is efficiently moved to the new location. In some embodiments, PID controller uses information from the laser interferometer sensors that determine the position of the fine stage to calculate the air bellows displacement and appropriate correcting force to be generated by the VCM. Due to the previously described connections between relevant components of Z object support and positioning device 138-1 and pressurized fluid 52-2 in air bellows 50-1, vertical support member 46 moves in the Z direction as a result. However, due to the non-zero stiffness of air bellows 50-1, in some embodiments, vertical support member 46 does not supply the desired force on object 42.

A Z position measuring device 140, such as, for example, an encoder 140-1, may be mounted to detect motion in the Z direction and to provide feedback to control system controlling the current in armature coil 128 of VCM 126. In some embodiments, Z encoder 140-1 detects motion of vertical support member 46-1. Z encoder 140-1 collects information on the movement in the Z direction of vertical support member 46-1. The controller may use the information obtained from Z encoder 140-1 to adjust VCM 126 current through armature coil 128.

In some embodiments, a Z encoder 140-1 or a measuring device (sensor) can measure the displacement of vertical support member relative to ground 58. Multiplying this displacement by the known stiffness of air bellows 50-1, a correction force to be applied by VCM 126 can be calculated. The typical stiffness of air bellows 50-1 is within the range from about 1000 N/m to about 10,000 N/m. In effect, VCM 126 is controlled to create a negative stiffness that counteracts the positive stiffness of air bellows 50, creating a “net stiffness” of the positioning device. In some embodiments, the “net stiffness” is less than about 100, 90, 80, 70, 60, 50, 40, 30, 20, and about 10 N/m.

A method of modeling the vertical stiffness of an air bellows includes slowly moving the VCM through its normal operating range. At various positions in this range, the air bellows position and the VCM force required to maintain the Z actuator at that position are recorded. Dividing the VCM force by the actuator position give the correct stiffness value (N/m). This measurement technique has the additional advantage of compensating for errors in the position measurement and VCM force constant.

Another embodiment of a Z support and positioning device 138 according to some embodiments of the invention is illustrated in FIG. 23. This embodiment, Z support and positioning device 138-2, incorporates Z support 40-2 illustrated in FIG. 10 modified to incorporate a VCM 126. Only the modified components will be described in detail. In some embodiments, Z support and positioning device 138-2 includes a projection 97 that may be rigidly connected to the object to be supported. Projection 97 allows both the Z support force and positioning force to be applied at the point of attachment to object 42. In some embodiments, VCM housing 132 is rigidly connected to projection 97 and, therefore, is rigidly connected to object 42. In some embodiments, an annular air bearing member 44-2 circumferentially surrounds VCM 126 and forms an annular air bearing 53 between its upper bearing surface 45 and a bottom surface of projection 97. In some embodiments, object 42, projection 97, and VCM housing 132 have a limited range of motion in the X and Y direction with respect to Z support 40-2, as limited by clearance between the inner diameter of annular air bearing member 44-2 and the outer diameter of VCM housing 132. In some embodiments, object 42, projection 97, and VCM housing 132 have a limited range of motion in the X and Y direction with respect to Z support 40-2, as limited by clearance between the inner diameter of VCM housing 132 and the outer diameter of VCM armature coil 128. In some embodiments, object 42, projection 97, and VCM housing 132 have a limited range of motion in the X and Y direction with respect to Z support 40-2, as limited by clearance between the inner diameter of armature coil 128 and the outer diameter of permanent magnet 130.

The dimensions of annular air bearing member 44-2 may also affect the efficiency of VCM 126. If the center of rotation determined by the radius of the spherical bearing 59 matches the VCM center, then any rotation of object 42 and, by virtue of their rigid connection, projection 97 and VCM housing 132 will minimize the changed distances between armature coil 128 and permanent magnets 130. Note that FIG. 23 does not illustrate a matched VCM center and center of rotation.

In some embodiments, including the one illustrated in FIG. 23, VCM armature coil 128 and liquid cooling can 142 (not illustrated for simplicity) are rigidly mounted to structure consisting of rigid walls 50-2, which is rigidly connected to main frame 48-5 (main frame 48-3 lengthened to accommodate VCM 126).

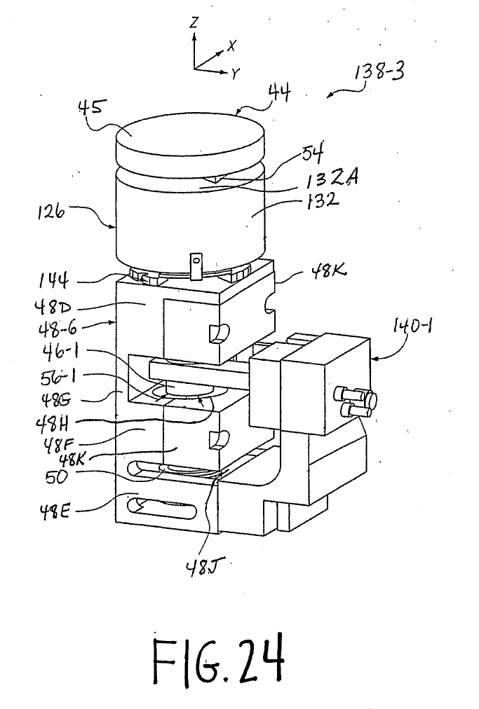

Yet another Z support and positioning device 138-3 according to some embodiments of the invention is illustrated in FIG. 24. In some embodiments, Z support and positioning device 138-3 includes a disc-shaped air bearing member 44-1, a flexure 54-6, VCM 126, a hollow, cylindrical shaft 46-1, a main frame 48-6, an air bellows 50-1, and a Z position measurement device 140.

In some embodiments, main frame 48-6 forms multiple air bushings 56-1 around hollow, cylindrical shaft 46-1. The at least one air bushing 56-1 may be supplied pressurized fluid through pathways (not shown) in either hollow, cylindrical shaft 46-1 or main frame 48-6.

In some embodiments, including the one illustrated in FIG. 24, object support and positioning device 138-3 uses an air bellows 50-1 for pressurized fluid 52-1 and an encoder 140-1 as Z position measurement device 140, as previously described with regard to the embodiment illustrated in FIGS. 20 and 21.

In some embodiments, including the one illustrated in FIG. 24, a flexure 54-6 connects air bearing member 44-1 and VCM housing 132. In some embodiments, including the one illustrated in FIG. 24, main frame 48-6 is generally “E” shaped and includes an upper bar section 48D, a lower bar section 48E, an intermediate bar section 48F positioned between upper bar section 48D and lower bar section 48E and a rear bar section 48G that connects upper, intermediate, and lower bar sections 48D, 48F, and 48E together. In some embodiments, including the one illustrated in FIG. 24, upper bar section 48D and intermediate bar section 48F include an aperture 48H for receiving hollow, cylindrical shaft 46-1 and air bushing 56-1, and lower bar section 48E includes a slot 48J for receiving air bellows 50-1. In some embodiments, main frame 48-6 may comprise several removable sections to facilitate assembly with vertical support member 46 or other desired components. For example, as illustrated in FIG. 24, upper bar section 48D and intermediate bar section 48F each include a selectively removable section 48K.

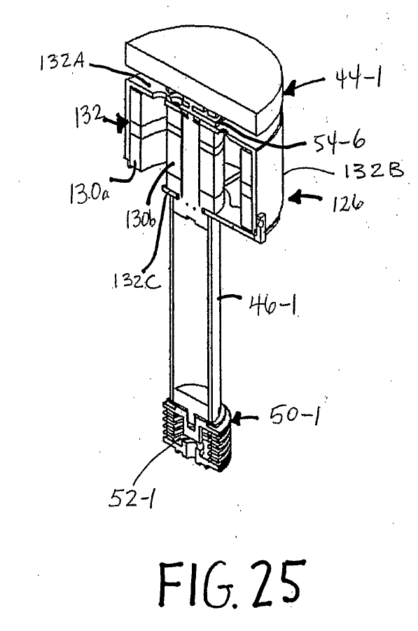

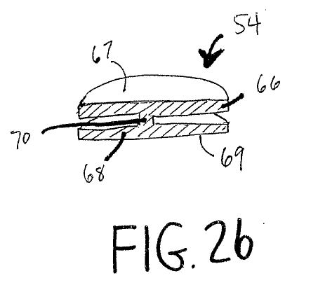

As seen in FIG. 25, the vertical support force may be transmitted from air bellows 50-1 through shaft 46-1 through VCM housing 132 through flexure 54-6 through air bearing member 44-1. In some embodiments, VCM housing 132 includes a top circular wall 123A, a cylindrical tubular wall 132B and a generally circular bottom wall 132C having opening through which mounting 144 (not shown) may protrude. Permanent magnets 130a and 130b are rigidly attached to at least one wall of VCM housing 132. In some embodiments, including the one illustrated in FIG. 25, VCM housing 132 is not rigidly connected to object 42. In some embodiments, top wall 132 is in contact with bottom surface 69 (shown in FIG. 26) of flexure 54-6 and top surface 67 (shown in FIG. 26) of flexure 54-6 is in contact with a bottom, mounting surface of air bearing member 44-1. In some embodiments, the vertical positioning force may be transmitted from VCM housing 132 through flexure 54-6 through air bearing member 44-1 through air bearing 53 to object 42. Because not all of these components have infinite vertical stiffness, this embodiment of a Z support and positioning device may not have the servo bandwidth of an embodiment in which the VCM is rigidly attached to object 42.

As seen in FIG. 26, in some embodiments, flexure 54-6 comprises an upper portion 66, a single “waist” 70, and a lower portion 68. In some embodiments, upper portion 66 and lower portion 68 each comprises a disc of significantly greater diameter than the diameter of waist 70. In some embodiments, upper portion 66 and lower portion 68 may be disk about 20 mm in diameter and about 3 mm thick. In some embodiments, waist 70 may be a disk or cylinder about 1 mm in diameter and about 1 mm thick. In some embodiments, upper portion 66 and lower portion 68 may be about 23 mm in diameter and about 2.5 mm thick.

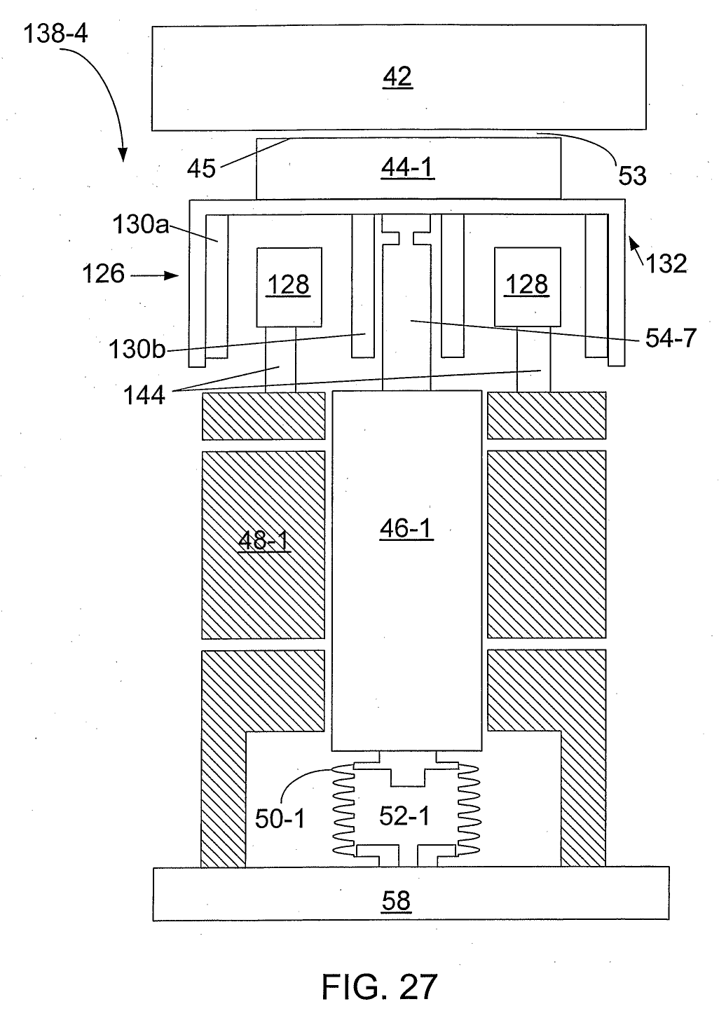

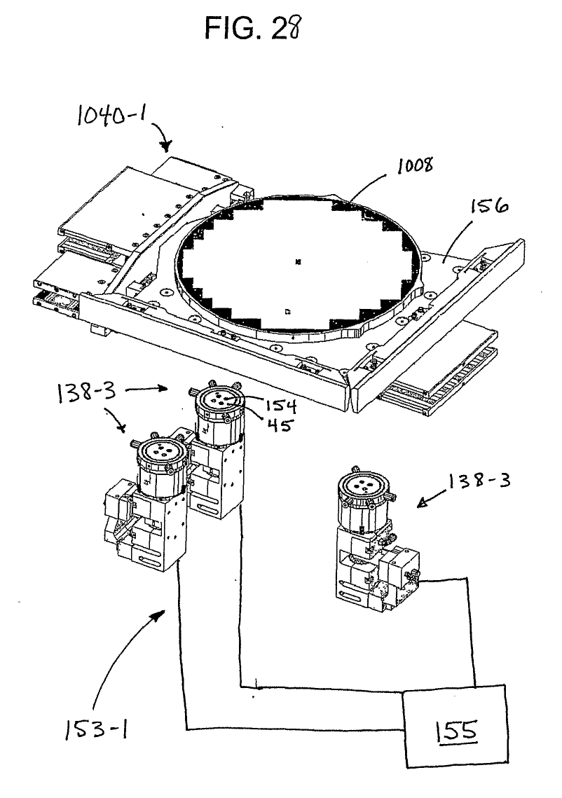

FIG. 27 illustrates another Z support and positioning device 138-4 according to some embodiments of the invention. Z support and positioning device 138-4 includes Z support device 40-1 except as modified with a VCM 126 and flexure 54-7. As illustrated in FIG. 27, flexure 54-7 is a simplified version of 54-5 illustrated in FIG. 22, without annular projection 152. VCM 126 is partially illustrated for ease of viewing how it interfaces with the components of Z support device 40-1 (liquid cooling can 142 and bottom wall 132C are not shown). In some embodiments, including Z support and positioning device 138-4 illustrated in FIG. 27, air bearing member 44-1 may be rigidly attached to VCM housing 132, and flexure 54-7 attached to VCM housing 132. Thus, in some embodiments, flexure 54 may be directly connected to vertical support member 46, illustrated in FIG. 27 as hollow, cylindrical shaft 46-1, and connected to the moving component of VCM 126, illustrated in FIG. 27 as permanent magnets 130a & b through VCM housing 132.

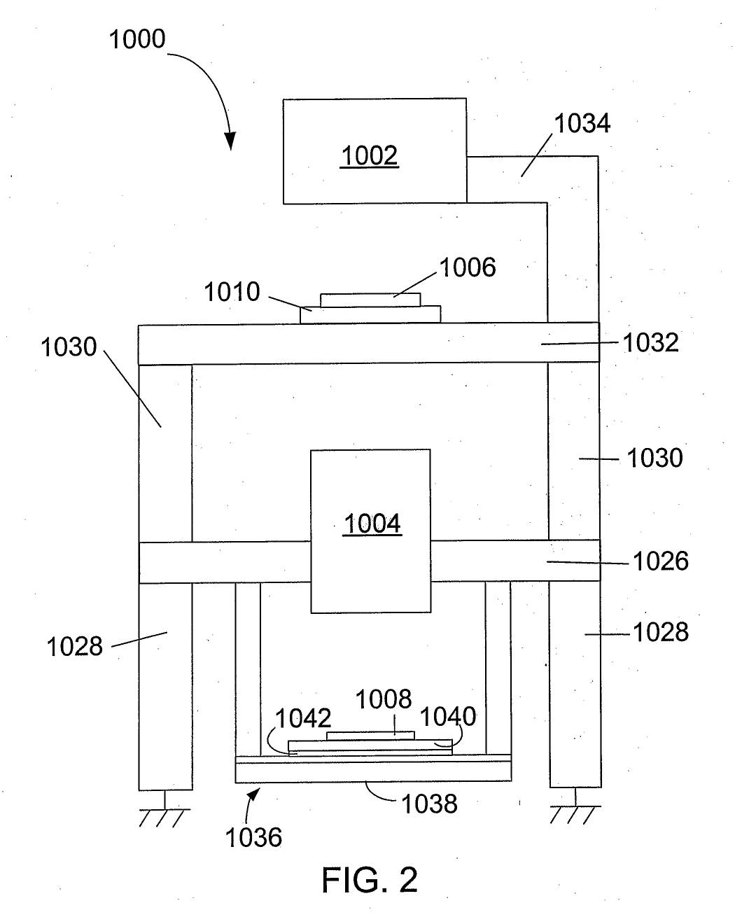

In some applications, object 42 supported by air bearing member 44 is a portion of a fine stage 1040 (FIG. 2). In application to lithography systems, three Z support and positioning devices 138 may be mounted on coarse stage 1038 (FIG. 2) to support and position fine stage 1040 in the Z and theta X and theta Y DOF. Together coarse stage 1038, three Z support and positioning devices 138, and fine stage 1040 move fine stage table 156 to position a workpiece, such as a wafer, for processing.

As seen best in FIG. 28, which illustrates an exploded view of a Z support and positioning system 153-1. Z support and positioning system 153-1 includes three Z support and positioning device 138-3 located at three non-linear points on a bottom surface of fine stage table 156. A controller 155 may receive target Z positions for each air bearing surface 45 and may control the respective VCM's armature coil current to achieve the desired position. As three points define a plane, control over just the Z position of air bearing surface 45 for each of the three Z support and positioning devices will define the orientation of a fine stage 1040-1 supported by a Z support and positioning system 153.

In FIG. 28, all three Z support and positioning devices 138 are the embodiment illustrated in FIG. 24 (Z support and positioning device 138-3), with additional details of air bearing member 44 illustrated. In some embodiments, air bearing member 44 is a vacuum pre-loaded orifice-type air bearing member 44-6. Air bearing member 44-5 defines internal pathways (not shown, but similar to pathways 90 of bearing member 88 of FIG. 16) supplying pressurized fluid, e.g., compressed air, from at least one opening on the circumferential perimeter of air bearing member 44-6 to four small holes 154 on bearing surface 45 of air bearing member 44-6 when connected to a supply of pressurized fluid. In some embodiments, air bearing member 44-6 is disc shaped and has four possible locations for an external air fitting. In general, only a pressurized air fitting need be connected, but preferably two are used, one for the pressurized fluid, the other for vacuum as discussed above for “pre-loading.”.

The higher the stiffness of fine stage table 156, the better the ability of the positioning systems according to some embodiments of the invention contacting discrete portions (only) of fine stage table 156 to move all parts of fine stage table 156 at the same speed and with the same accuracy. Stated another way, the stiffness of a fine stage affects the servo response of a Z positioning system.

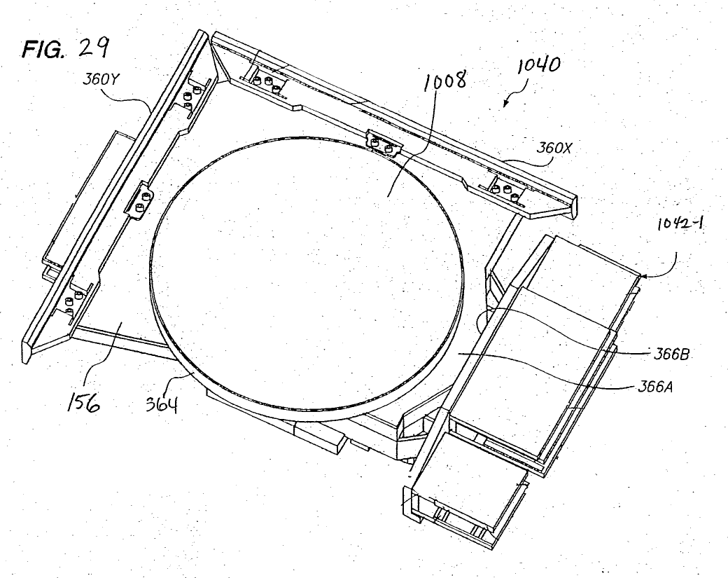

FIG. 29 illustrates a perspective top view of fine stage 1040, including an X mirror 360X and a Y mirror 360Y that are used in a measurement system, a portion of a second positioning system 1042-1, and wafer 1008. In some embodiments, fine stage 1040-1 includes a table 156 and a chuck 364 secured to table 156 that holds wafer 1008. In some embodiments, table 156 is roughly rectangular and the right side of table 156 defines a cantilevering, necked region 366A that defines a first mounting surface 366B.

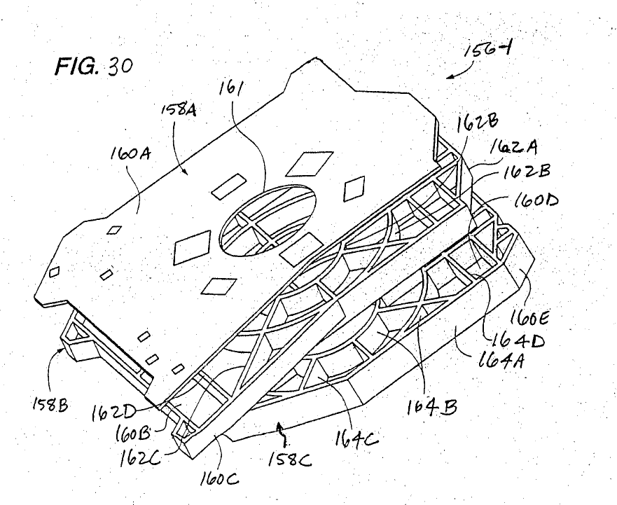

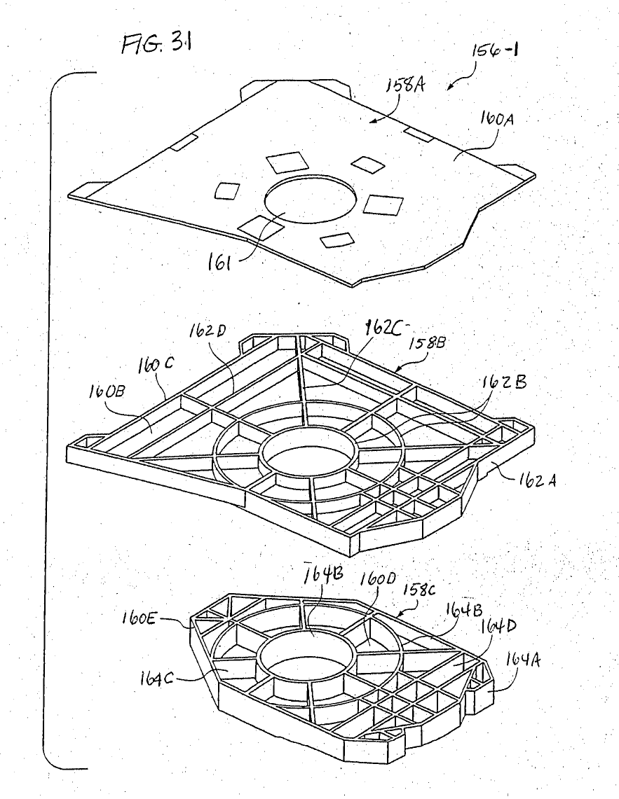

FIGS. 30 and 31 are alternative, exploded perspective views of one embodiment of table 156-1. As illustrated in FIGS. 30 and 31, fine stage table 156-1 is a ceramic box structure for high stiffness. In some embodiments, including the one illustrated in FIGS. 30 & 31, table 156-1 includes an upper first table section 158A, an intermediate second table section 158B that is fixedly secured to the bottom of first table section 158A, and a lower third table section 158C that is fixedly secured to the bottom of second table section 158B. Alternatively, table 156-1 could be designed with fewer than three or more than three table sections. With this design, the sections of table 156-1 can be designed to achieve the desired characteristics of table 156.

The design of each table section 158A, 158B, 158C can vary. In FIGS. 30 and 31, first table section 158A includes a generally flat plate shaped upper plate 160A. Second table section 158B includes a generally flat plate shaped intermediate plate 160B and a plurality of intermediate walls 160C that extend transversely to and cantilever upward from intermediate plate 160B. Somewhat similarly, third table section 158C includes a generally flat plate shaped lower plate 160D and a plurality of lower walls 160E that extend transversely to and cantilever upward from lower plate 160D.

The shape, positioning, and number of walls 160C, 160E can be varied to achieve the desired stiffness, weight, and vibration characteristics of table 156-1. In some embodiments, intermediate walls 160C include an outer rectangular shaped perimeter wall 162A, two, coaxial tubular shaped walls 162B, a plurality of radial walls 162C that extend radially from the inner of the two, coaxial, tubular-shaped walls 162B towards outer perimeter wall 162A, and three, spaced apart cross-brace walls 162D. Somewhat similarly, in some embodiments, lower walls 160E include an outer rectangular shaped perimeter wall 164A, two, coaxial, tubular-shaped walls 164B, a plurality of radial walls 164C that extend radially from the inner of the two, coaxial, tubular-shaped walls 164B towards outer perimeter wall 164A, and three, spaced apart cross-brace walls 164D.

In some non-exclusive embodiments, one or more of the walls has a thickness of approximately 1, 2, 5, 7, 10, 15 or 20 mm.

Table sections 158A, 158B, 158C can be fixed together with an adhesive, fasteners, welds, brazing, or other suitable fashion. In some embodiments, at least one of table sections 158A, 158B, 158C is made of a ceramic material. With the sections 158A, 158B, 158C secured together, table 156-1 defines a plurality of spaced apart cavities.

In should be noted that table 156-1 illustrated in FIGS. 30 and 31 is a box type structure that includes a plurality of walls that are positioned therein to provide a lightweight table 156-1 that is very stiff. This table 156-1 also includes an aperture 161 that facilitates replacement of chuck 364 (illustrated in FIG. 29).

In some embodiments, table 156-1 is approximately 350 mm by 450 mm by 40 mm thick. Further, in some embodiments, table 156-1 has a mass of less than approximately 7, 6.5, 6, 5.8, 5.5 or 5 kg. Moreover, in some embodiments, table 156-1 has a first vibration frequency of at least approximately 500, 600, 700, 800, or 1000 Hz.

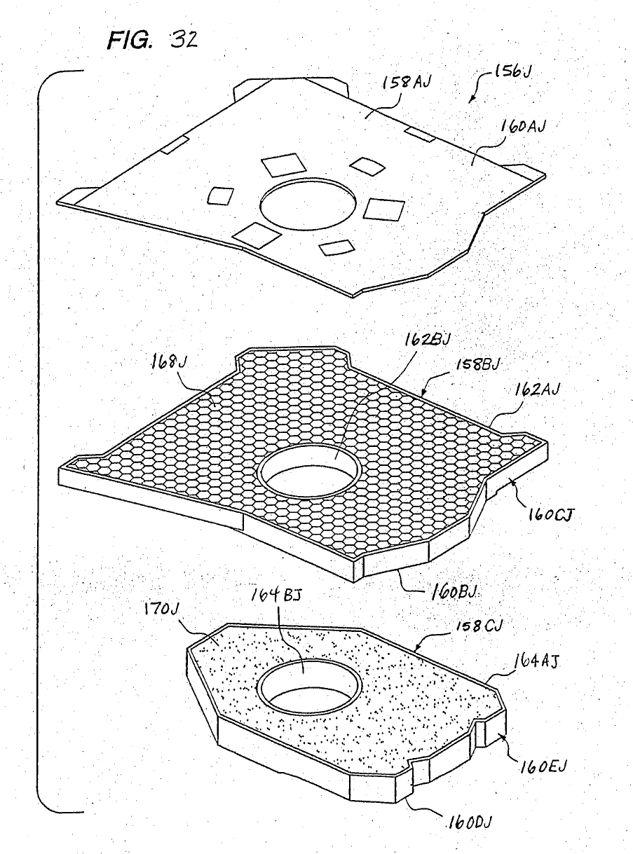

An alternate construction of a fine stage table 156 is a hollow type-monolithic box structure that is lightweight and has high stiffness. FIG. 32 illustrates an exploded perspective view of a such a table 156J. In some embodiments, table 156J includes an upper first table section 158AJ, an intermediate second table section 158BJ that is fixedly secured to the bottom of first table section 158AJ, and a lower third table section 158CJ that is fixedly secured to the bottom of second table section 158BJ. Alternatively, table 156J could be designed with fewer than three or more than three table sections.

In FIG. 32, first table section 158AJ includes a generally flat plate shaped upper plate 160AJ. Second table section 158BJ includes a generally flat plate shaped intermediate plate 160BJ and a plurality of intermediate walls 160CJ that extend transversely to and cantilever upward from intermediate plate 160BJ. Somewhat similarly, third table section 158CJ includes a generally flat plate shaped lower plate 160DJ and a plurality of lower walls 160EJ that extend transversely to and cantilever upward from lower plate 160DJ.

In some embodiments, intermediate walls 160CJ include an outer perimeter wall 162AJ, and a tubular shaped inner wall 162BJ. Somewhat similarly, in some embodiments, lower wall 160EJ includes an outer perimeter wall 164AJ and a tubular shaped inner wall 164BJ.

In some embodiments, one or more of table sections 158AJ, 158BJ, 158CJ includes a honeycomb type structure 168J and/or a foam material 170J. In FIG. 32, intermediate second table section 158BJ includes a honeycomb type structure 168J positioned between intermediate walls 160CJ, and lower third table section 158CJ includes a foam material 170J positioned between lower walls 160EJ. Examples of a honeycomb type structure 168J include a plurality of very thin walls that can be made of a number of materials such as aluminum, cardboard, or fiber reinforced plastic. Examples of a foam material 170J include a polymer foam.

Yet another aspect of the present invention is a connecting method for a drive system for X and Y movement that minimizes deformation of table 156, in particular, at least the portion supporting a workpiece. In some embodiments, table 156 includes a multistage structure and X and Y movers (a second positioning system 1042-1) are connected to the lowest part of the multistage structure.

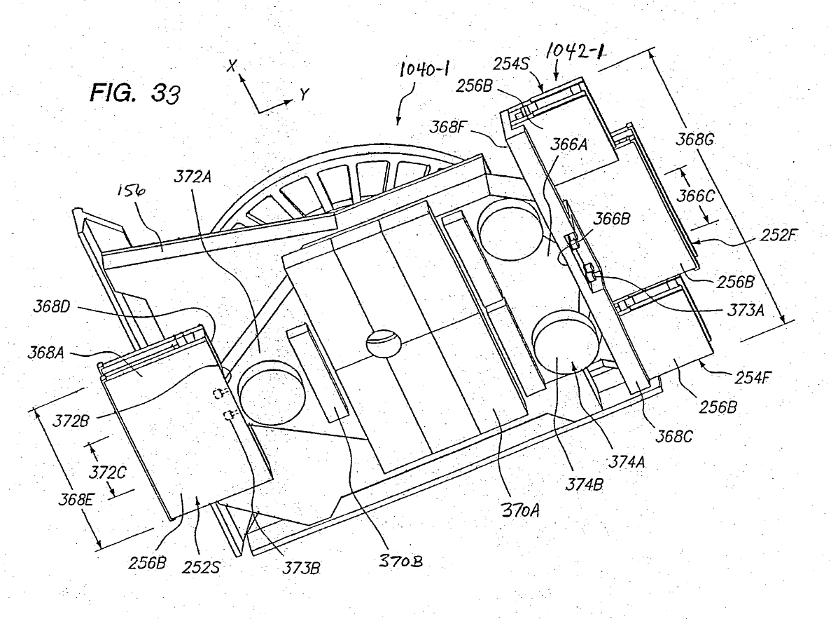

FIG. 33 illustrates a perspective bottom view of fine stage 1040-1, including a portion of a second positioning system 1042-1. FIG. 33 illustrates that fine stage 1040-1 includes one or more balance weights 370A, and one or more stops 370B that are fixedly secured to table 156. Balance weights 370A are used to adjust the center of gravity (not shown) of fine stage 1040-1. Accordingly, the number and location of balance weights 370A can be varied to achieve the desired center of gravity. In some embodiments, one or more fasteners (not shown) are used to selectively each of balance weights 370A and stops 370B to table 156.

Stops 370B provide a safe contact area for fine stage 1040-1. With this design, when Z positioning and support devices 138 (not shown in FIG. 33) are turned off, stops 370B can engage lower stage 1038 (not shown in FIG. 33) to support fine stage 1040-1. The design and number of stops 370B can vary. In FIG. 33, fine stage 1040-1 includes three spaced apart, generally rectangular shaped stops 370B.

FIG. 33 illustrates that the left side of table 156 defines a cantilevering, second necked region 372A that defines a second mounting surface 372B that is substantially opposite from first mounting surface 366B. First mounting surface 366B has a first surface length 366C and a first surface area. Similarly, second mounting surface 372B has a second surface length 372C and a second surface area. In some designs, surface lengths 366C, 372C and surface areas are relatively small. In some embodiments, each surface length 366C, 372C is less than approximately 10, 20, 30, 40, 50 or 100 mm. Further, in some embodiments, each surface area is less than approximately 5, 10, 20, 30, 40, or 50 cm².

A mover mounting surface 368D of mover housing 368A of each X mover 252F, 252S has a housing length 368E and an attachment side area. In some embodiments, each housing length 368E is greater than approximately 30, 50, 70, 100, 125, 150, 175, or 200 mm. Further, in some embodiments, each attachment side area is greater than approximately 10, 20, 40, 50, 75, or 100 cm².

In some embodiments, housing length 368E of second X mover 252S is greater than second surface length 372C and the housing side area is greater than the surface area of second mounting surface 372B. In some embodiments, housing length 368E of second X mover 252S is at least approximately 20, 40, 60, 80, 100, 150, 200, 250, 300, 350, 400, 450, or 500 percent longer than second surface length 372C. Further, in some embodiments, the housing side area of second X mover 252S is at least approximately 20, 40, 60, 80, 100, 200, 300, 400, 500, 600, 700, 800, 900, or 1000 percent larger than the surface area of second mounting surface 372B. With this design, second mover component 256B of second X mover 252S cantilevers away from second necked region 372A of table 156.

It should be noted that temperature changes in second mover component 256B of second X mover 252S can cause deformation, e.g. a change in length or bending of second mover component 256B. The temperature changes can be caused by heat from the coils of second X mover 252S and thermal radiation. Because of the relatively small second surface length 372C and the gap between second mover component 256B and second necked region 372A of table 156, the effects of deformation of the second mover component 256B on fine stage table 156 are reduced.

Somewhat similarly, a mover mounting surface 368F of mounting bracket 368C has a bracket length 368G and a bracket surface area. In some embodiments, bracket length 368G is greater than approximately 50, 100, 150, 200, 250, or 300 mm. Further, in some embodiments, the bracket surface area is greater than approximately 10, 20, 40, 60, 80, 100, 120, or 150 cm².

In some embodiments, bracket length 368G is greater than surface length 366C of first mounting surface 366B and the bracket surface area is greater than the surface area of first mounting surface 366B. In some embodiments, bracket length 368G is at least approximately 20, 40, 60, 80, 100, 150, 200, 250, 300, 350, 400, 450, or 500 percent longer than surface length 366C of first mounting surface 366B. Further, in some embodiments, the bracket surface area is at least approximately 20, 40, 60, 80, 100, 200, 300, 400, 500, 600, 700, 800, 900, or 1000 percent bigger than the surface area of first mounting surface 366B. With this design, mounting bracket 368C with second mover component 256B of movers 252F, 254F, 254S cantilever away from first necked region 366A of table 156.

It should be noted that temperature changes in second mover component 256B of first X mover 252F and Y movers 254F, 254S can cause deformation, e.g., bending of mounting bracket 368C. Because of the relatively small first surface length 366C, effects of deformation of the mounting bracket 368C on fine stage table 156 are reduced.

In some embodiments, fine stage 1040-1 also includes (i) a first fastener assembly 373A for selectively securing mounting bracket 368C with second mover components 256B of first X mover 252F and Y movers 254F, 254S to first mounting surface 366B, and (ii) a second fastener assembly 373B (illustrated in phantom) for selectively securing mover housing 368A of second X mover 252S to second mounting surface 372B. With this design, second mover components 256B of X movers 252F, 252S and Y movers 254F, 254S can be easily replaced. This leads to a modular type design where different types of movers can be readily changed on the stage assembly. Stated in another fashion, with this design, one or more movers of second mover assembly 224 can easily be reconfigured.

It should be noted that in some embodiments, a second mover component (not shown) of first X mover 252F is positioned above the center of gravity of fine stage 1040-1 and a second mover component (not shown) of second X mover 252S is positioned below the center of gravity of fine stage 1040-1. Further, X movers 252F, 252S are positioned to direct a net force through the center of gravity of fine stage 1040-1.

FIG. 33 also illustrates that table 156 includes one or more table pads 374A that interact with Z positioning and support devices 138. The number, location, size and shape of table pads 374A can vary. In some embodiments, table 156 includes three spaced apart table pads 374A. Further, each table pad 374A is generally hollow disk shaped and includes a generally flat bearing surface 374B that faces Z positioning and support devices 138.

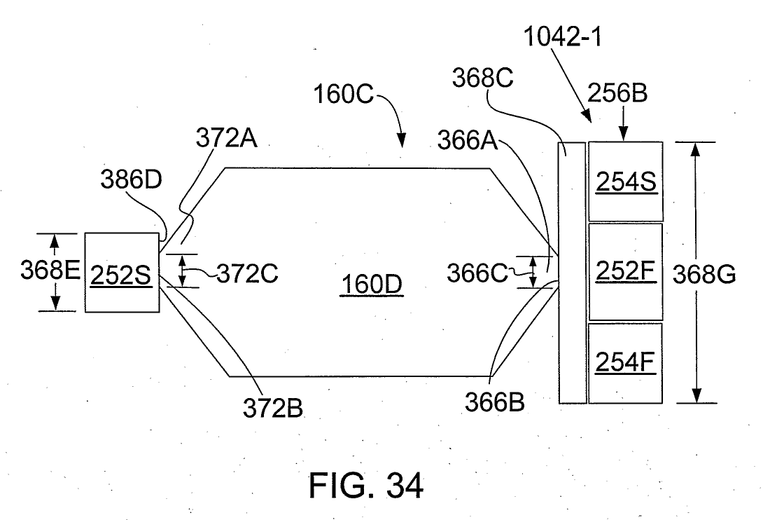

FIG. 34 is a simplified illustration of a portion of table 156 and a portion of second mover components 256B of second positioning system 1042-1. In this illustration, many of the surface features of table 156 have been removed. In particular, this illustration highlights first necked region 366A and second necked region 372A of table 156, as well as the connection of X and Y mover components of a second positioning system to lower stage 160C of table 156. By connecting the X and Y movers to the lowest of the multistage table 156, any deformation to upper stages of multistage table 156 may be reduced.

FIG. 34 also illustrates that second mover component 256B of first X mover 252F, and Y movers 254F, 254S are secured to the right side of table 156, and second mover component 256B of second X mover 252S is secured to the left side of table 156. The mounting bracket 368C secures mover housing 368A of first X mover 252F, and Y movers 254F, 254S to table 156.

FIG. 34 also highlights the relationship between (i) first surface length 366C of first mounting surface 366B and bracket length 368G of mounting bracket 368C, and (ii) second surface length 372C of second mounting surface 372B and the housing length 368E of mover mounting surface 368D.

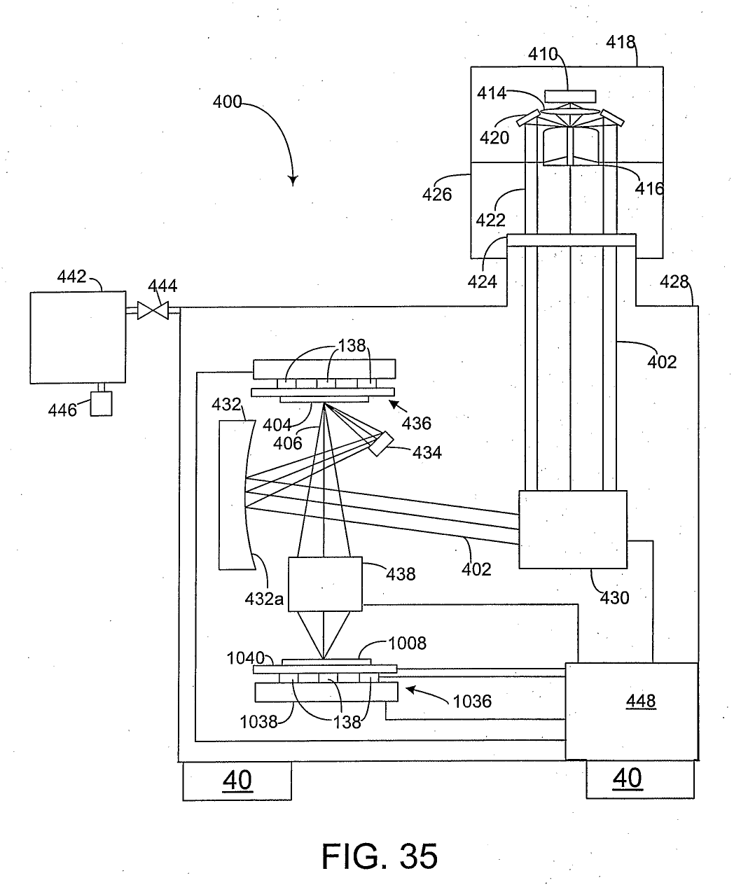

An exemplary extreme ultra-violet (“EUV”) lithographic exposure system 400 with which any of the foregoing embodiments of Z support and positioning systems can be used to support and position a fine stage (whether a wafer stage or a reticle stage) is shown schematically in FIG. 35. Any Z support can be used, but it may be desirable to use an embodiment of Z support 40 like that illustrated in FIG. 14, due to the vacuum environment in which EUV lithography often occurs to reduce the cost of maintaining the environmental pressure (vacuum). Many of the components and their interrelationships in this system are known in the art, and hence are not described in detail herein.

Lithographic exposure system 400 is a projection-exposure system that performs step-and-scan lithographic exposures using light in the extreme ultraviolet (“soft X-ray”) band, typically having a wavelength in the range of 8 to 14 nm (nominally 13 nm). Lithographic exposure involves directing an EUV illumination beam 402 to a pattern-defining reticle 404. Illumination beam 402 reflects from reticle 404 while acquiring an aerial image of the pattern portion defined in the illuminated portion of reticle 404. The resulting “patterned beam” 406 is directed to an exposure-sensitive substrate 408, on which a latent image of the pattern is formed.

To produce illumination beam 402, a laser light source 410 may be situated at the extreme upstream end of system 400. Laser light source 410 produces a beam 412 of laser light having a wavelength in the range of infrared to visible. For example, laser light source 410 can be a YAG or excimer laser employing semiconductor laser excitation. Laser light 412 emitted from laser light source 410 is focused and directed by a condensing optical system 414 to a laser-plasma light source 416. Laser-plasma light source 416 can be configured, for example, to generate EUV radiation having a wavelength of 8 to 13 nm.

A nozzle (not shown) is disposed in laser-plasma light source 416, from which xenon gas is discharged. As the xenon gas is discharged from the nozzle in laser-plasma light source 416, the gas is irradiated by high-intensity laser light 412 from laser light source 410. The resulting intense irradiation of the xenon gas causes sufficient heating of the gas to generate a plasma. Subsequent return of Xe molecules to a low-energy state results in the emission of EUV light from the plasma.

Since EUV light has low transmissivity in air, its propagation path may be enclosed in a vacuum environment produced in a vacuum chamber 418. Also, since debris tends to be produced in the environment of the nozzle from which the xenon gas is discharged, vacuum chamber 418 desirably is separate from other chambers of system 400.

A paraboloid mirror 420, provided with, for example, a surficial multilayer Mo/Si coating, is disposed immediately upstream of laser-plasma light source 416. EUV radiation emitted from laser-plasma light source 416 enters paraboloid mirror 420, and only EUV radiation having a wavelength of, for example, 8 to 13 nm is reflected from paraboloid mirror 420 as a coherent flux of EUV light 422 in a downstream direction (downward in the figure). EUV flux 422 then encounters a pass filter 424 that blocks transmission of visible wavelengths of light and transmits the desired EUV wavelength. Pass filter 424 can be made, for example, of 0.15 nm-thick beryllium (Be) or 100 nm thick zirconium (Zr). Hence, only EUV radiation (illumination beam 402) having the desired wavelength is transmitted through pass filter 424. The area around pass filter 424 is enclosed in a vacuum environment inside a chamber 426.

An exposure chamber 428 is situated downstream of pass filter 424. Exposure chamber 428 may be isolated from vibration by an embodiment of a Z support 40 according to some embodiments of the invention. Exposure chamber 428 contains an illumination-optical system 430 that comprises at least a condenser-type mirror and a fly-eye-type mirror. Illumination beam 402 from pass filter 424 is shaped by illumination-optical system 430 into a circular flux that is directed to the left in the figure toward an X-ray-reflective mirror 432. Mirror 432 may have a circular, concave reflective surface 432a and may be held in a vertical orientation (in the figure) by holding members (not shown). Mirror 432 comprises a substrate made, e.g., of quartz or low-thermal-expansion material such as Zerodur (Schott). Reflective surface 432a can be shaped with extremely high accuracy and coated with a Mo/Si multilayer film that is highly reflective to EUV light. Whenever EUV light having a wavelength in the range of 10 to 15 nm is used, the multilayer film on surface 432a can include a material such as ruthenium (Ru) or rhodium (Rh). Other candidate materials are silicon, beryllium (Be), and carbon tetraboride (B₄C).

A bending mirror 434 is disposed at an angle relative to mirror 432 to the right of mirror 432 in the figure. Reflective reticle 404, that defines a pattern to be transferred lithographically to substrate 408, is situated “above” bending mirror 434. Note that reticle 404 is oriented horizontally with reflective surface directed downward to avoid deposition of any debris on the patterned and reflective surface of reticle 404. Illumination beam 402 of EUV light emitted from illumination-optical system 430 is reflected and focused by mirror 432 and reaches the reflective surface of reticle 404 via bending mirror 434.

Reticle 404 has an EUV-reflective surface configured as a multilayer film. Pattern elements, corresponding to pattern elements to be transferred to substrate (or “wafer”) 408, are defined on or in a EUV-reflective surface. Reticle 404 is mounted on a reticle stage 436 that is operable to hold and position reticle 404 in the X, Y, and theta Z degrees of freedom as required for proper alignment of the reticle relative to substrate 408 for accurate exposure. Reticle stage 436 may include one or more Z support and positioning devices 138 to support and position reticle 404 in the three vertical degrees of freedom. The position of reticle stage 436 is detected interferometrically in a manner known in the art. Hence, illumination beam 402 reflected by bending mirror 434 is incident at a desired location on the reflective surface of reticle 404.

A projection-optical system 438 and substrate 408 are disposed downstream of reticle 404. Projection-optical system 438 comprises several EUV-reflective mirrors. Patterned beam 406 from reticle 404, carrying an aerial image of the illuminated portion of reticle 404, is “reduced” (demagnified) by a desired factor (e.g., ¼) by projection-optical system 438 and is focused on the surface of substrate 408, thereby forming a latent image of the illuminated portion of the pattern on substrate 408. So as to form the image carried by patterned beam 406, upstream-facing surface of substrate 1008 is coated with a suitable resist.

Substrate 1008 is mounted electrostatically or other by another appropriate mounting force via a “chuck” (not shown but well understood in the art) to a fine stage 1040 according to some embodiments of the invention. Fine stage 1040 may be supported and positioned relative to lower stage 1038 by three Z positioning and support devices according to some embodiments of the invention. The position of substrate stage 1040 is detected interferometrically, in a manner known in the art.

A pre-exhaust chamber 442 (load-lock chamber) is connected to exposure chamber 428 by a gate valve 444. A vacuum pump 446 is connected to pre-exhaust chamber 442 and serves to form a vacuum environment inside pre-exhaust chamber 442.

During a lithographic exposure performed using system 400 shown in FIG. 35, EUV light is directed by illumination-optical system 430 onto a selected region of the reflective surface of reticle 404. As exposure progresses, reticle 404 and substrate 1008 are scanned synchronously (by their respective stages 436, 1036) relative to projection-optical system 438 at a specified velocity ratio determined by the demagnification ratio of projection-optical system 438. Normally, because not all the pattern defined by reticle 404 can be transferred in one “shot,” successive portions of the pattern, as defined on reticle 404, are transferred to corresponding shot fields on substrate 1008 in a step-and-scan manner. By way of example, a 25 mm×25 mm square chip can be exposed on substrate 1008 with an IC pattern having a 0.07 μm line spacing at the resist on substrate 1008.

Coordinated and controlled operation of system 400 is achieved using a controller 448 connected to various components of system 400 such as illumination-optical system 430, reticle stage 436, projection-optical system 438, and substrate stage 1036. For example, controller 448 operates to optimize the exposure dose on substrate 1008 based on control data produced and routed to the controller from various components to which controller 448 is connected, including various sensors and detectors (not shown). Controller 448 may perform the functions described herein with respect to controller 155 for Z positioning and support system 153.

As described above, a photolithography system according to the above described embodiments can be built by assembling various subsystems, including each element listed in the appended claims, in such a manner that prescribed mechanical accuracy, electrical accuracy and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, total adjustment is performed to make sure that every accuracy is maintained in the complete photolithography system. Additionally, it is desirable to manufacture an exposure system in a clean room where the temperature and humidity are controlled.

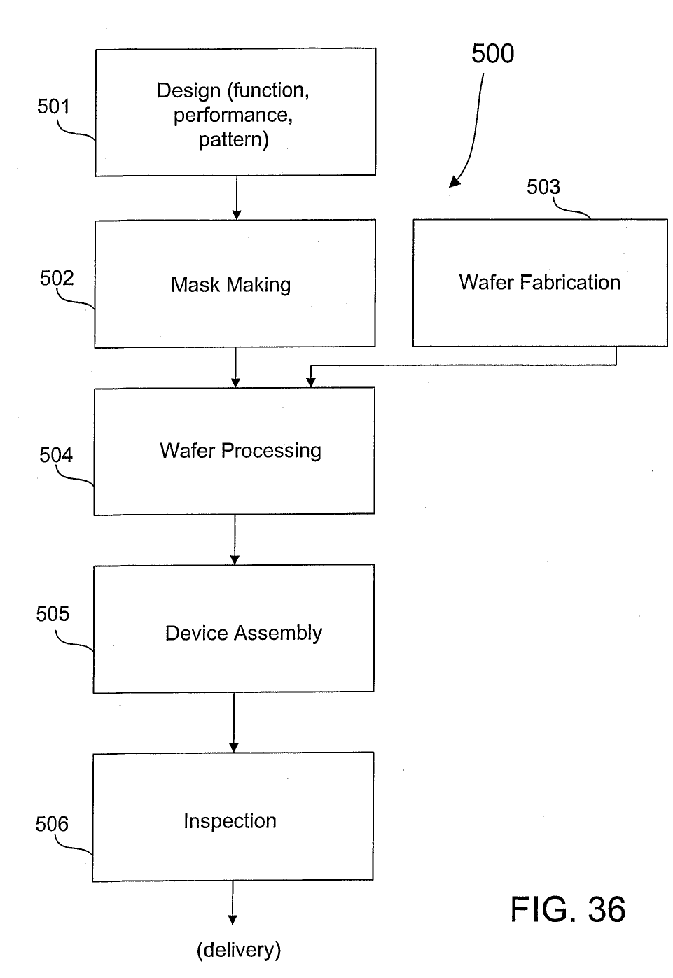

Further, semiconductor devices can be fabricated using the above described systems, by the process shown generally in FIG. 36. In step 501, the device's function and performance characteristics are designed. Next, in step 502, a mask (reticle) having a pattern is designed according to the previous designing step, and in a parallel step 503, a wafer is made from a silicon material. The mask pattern designed in step 502 is exposed onto the wafer from step 503 in step 504 by a photolithography system described hereinabove according to some embodiments of the invention. In step 505, the semiconductor device is assembled (including the dicing process, bonding process and packaging process), then finally the device is inspected in step 506.

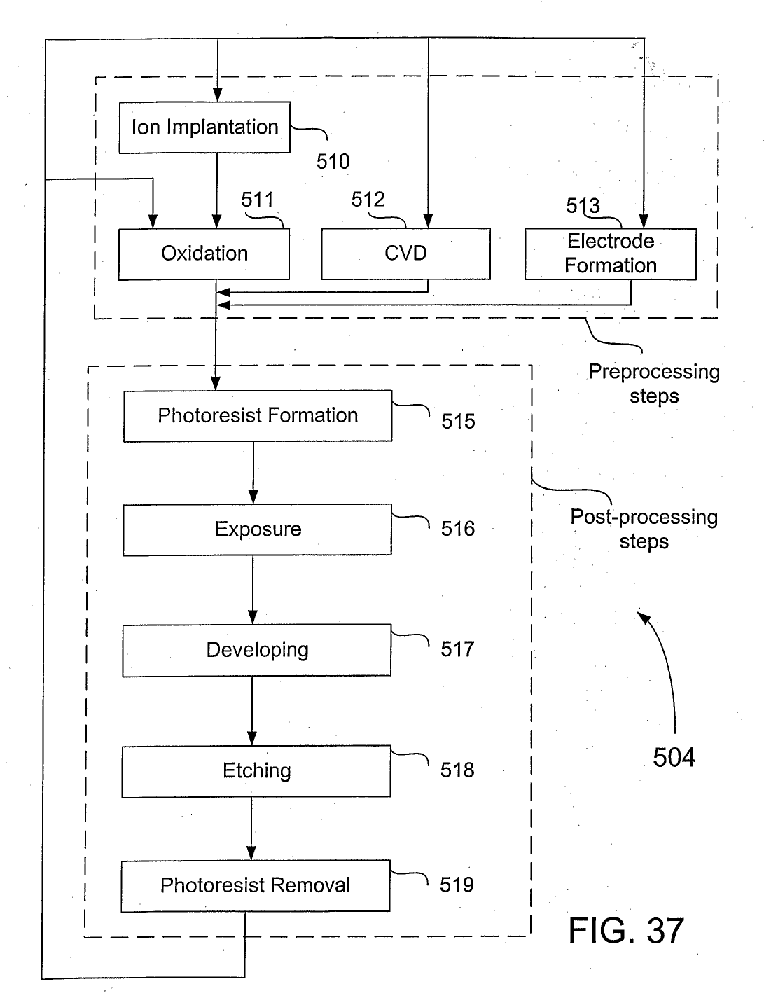

FIG. 37 illustrates a detailed flowchart example of the above-mentioned step 504 in the case of fabricating semiconductor devices. In step 511 (oxidation step), the wafer surface is oxidized. In step 512 (CVD step), an insulation film is formed on the wafer surface. In step 513 (electrode formation step), electrodes are formed on the wafer by vapor deposition. In step 514 (ion implantation step), ions are implanted in the wafer. The above mentioned steps 511-514 form the preprocessing steps for wafers during wafer processing, and selection is made at each step according to processing requirements.

At each stage of wafer processing, when the above-mentioned preprocessing steps have been completed, the following post-processing steps are implemented. During post-processing, initially, in step 515 (photoresist formation step), photoresist is applied to a wafer. Next, in step 516, (exposure step), the above-mentioned exposure device is used to transfer the circuit pattern of a mask (reticle) to a wafer. Then, in step 517 (developing step), the exposed wafer is developed, and in step 518 (etching step), parts other than residual photoresist (exposed material surface) are removed by etching. In step 519 (photoresist removal step), unnecessary photoresist remaining after etching is removed.

Multiple circuit patterns are formed by repetition of these preprocessing and post-processing steps.

Other embodiments according to some embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. An apparatus for supporting an object in the Z direction comprising:
an air bearing member;
a vertical support member;
a flexure connecting the vertical support member to the air bearing member; and
a housing for pressurized gas;
wherein when the housing is filled with pressurized gas, a pressure differential acts on an area of the vertical support member to provide a desired force on an object.

2. The apparatus of claim 1, wherein the flexure comprises a first section able to bend about one of the X and Y axes and a second section able to bend about the other of the X and Y axes.

3. The apparatus of claim 1, wherein the flexure comprises a section able to bend about the X and Y axes.

4. The apparatus of claim 1, wherein the housing comprises rigid walls and an opening adapted to permit at least a portion of the vertical support member to enter the housing.

5. The apparatus of claim 4, wherein the opening in the housing is in a bottom rigid wall.

6. The apparatus of claim 1, wherein the pressurized gas is negatively pressurized relative to ambient.

7. The apparatus of claim 1, wherein the housing comprises an air bellows mechanically connected to the vertical support member.

8. The apparatus of claim 1, wherein the pressurized gas is positively pressurized relative to ambient.

9. The apparatus of claim 1, wherein the housing contains a substantially constant amount of pressurized fluid.

10. The apparatus of claim 1, wherein the housing contains fluid at a substantially constant pressure.

11. The apparatus of claim 1, wherein the housing comprises a gas inlet.

12. The apparatus of claim 1 further comprising a vertical bushing to guide the motion of the vertical support member.

13. The apparatus of claim 1, wherein the object is below the apparatus.

14. The apparatus of claim 1, wherein the object is above the apparatus.

15. The apparatus of claim I further comprising:
an air bearing housing surrounding the air bearing member, and
wherein the air bearing housing reduces the volume of gas escaping to the surrounding environment.

16. The apparatus of claim 15 further comprising:
a main frame comprising
at least one air bushing to guide the motion of the vertical support member; and
at least one vacuum guard ring adjacent to the at least one air bushing;
wherein the at least one vacuum guard ring reduces the volume of gas escaping to the surrounding environment.

17. An apparatus for supporting an object in the Z direction comprising:
an air bearing member having a planar bearing surface and a spherical bearing surface;
a vertical support member having a bearing surface that mates with one of the planar bearing surface and the spherical bearing surface of the air bearing;
a main frame connected to ground and guiding the vertical support member in the Z direction;
an air bellows mechanically connected to the vertical support member, wherein when filled with a pressurized fluid, the air bellows exerts a desired force on the vertical member, a portion of which is transmitted through the air bearing member to support the object.

18. The apparatus of claim 17, wherein the spherical bearing surface of the air bearing member is convex.

19. The apparatus of claim 17, wherein the spherical bearing surface of the air bearing member is concave.

20. The apparatus of claim 17, wherein the bearing surface of the vertical support member is spherical.

21. The apparatus of claim 17 wherein the bearing surface of the vertical support member is planar.

22. The apparatus of claim 17, wherein the air bellows contains a substantially constant amount of pressurized fluid.

23. The apparatus of claim 17, wherein the air bellows contains fluid at a substantially constant pressure.

24. The apparatus of claim 17, wherein the air bellows comprises a gas inlet.

25. The apparatus of claim 17, wherein the object is below the apparatus.

26. The apparatus of claim 17, wherein the object is above the apparatus.

27. An apparatus for supporting and positioning an object in the Z direction comprising:
an air bearing member;
a vertical support member;
a flexure connecting the vertical support member to the air bearing member; and
a main frame guiding the motion of the vertical support member;
a housing for pressurized gas;
wherein when the housing is filled with pressurized gas, a pressure differential acts on an area of the vertical support member to provide a desired force on an object and
a voice coil motor comprising an armature coil rigidly connected to one of the main frame and the object to be positioned and at least one permanent magnet rigidly connected to the other of the main frame and the object to be positioned.

28. The apparatus of claim 27, wherein the flexure is concentrically located with the armature coil.

29. The apparatus of claim 27, wherein the flexure comprises a single section able to bend about the X and Y axes and having a single center of bending.

30. The apparatus of claim 29 wherein the center of bending of the flexure is coincident with the voice coil motor center.

31. The apparatus of claim 27, wherein the flexure comprises a first section able to bend about one of the X and Y axes and a second section able to bend about the other of the X and Y axes.

32. The apparatus of claim 27, wherein the pressurized gas is negatively pressurized relative to ambient.

33. The apparatus of claim 27, wherein the pressurized gas is positively pressurized relative to ambient.

34. The apparatus of claim 27, wherein the housing comprises rigid walls and an opening adapted to permit at least a portion of the vertical support member to enter the housing.

35. The apparatus of claim 34, wherein the opening in the housing is in a bottom rigid wall.

36. The apparatus of claim 27, wherein the housing comprises an air bellows mechanically connected to the vertical support member.

37. The apparatus of claim 27, wherein the housing contains a substantially constant amount of pressurized fluid.

38. The apparatus of claim 27, wherein the housing contains fluid at a substantially constant pressure.

39. The apparatus of claim 27, wherein the housing comprises a gas inlet.

40. The apparatus of claim 27, wherein the armature coil is rigidly connected to the main frame.

41. The apparatus of claim 27, wherein the armature coil is rigidly connected to the object to be positioned.

42. The apparatus of claim 27 further comprising a vertical bushing to guide the motion of the vertical support member.

43. The apparatus of claim 27 further comprising:
an air bearing housing surrounding the air bearing member, and
wherein the air bearing housing reduces the volume of gas escaping to the surrounding environment.

44. An apparatus for supporting and positioning an object in the Z direction comprising:
an annular air bearing member having a planar bearing surface and a spherical bearing surface;
a vertical support member having a bearing surface for mating with one of the planar bearing surface and the spherical bearing surface of the air bearing member;
a main frame guiding the motion of the vertical support member;
a housing for pressurized gas;
wherein when the housing is filled with pressurized gas, a pressure differential acts on an area of the vertical support member to provide a desired force on an object; and
a voice coil motor comprising an armature coil rigidly connected to one of the main frame and the object to be positioned and at least one permanent magnet rigidly connected to the other of the main frame and the object to be positioned, wherein the voice coil motor is disposed within a cylinder defined by the outer diameter of the annular air bearing member.

45. The apparatus of claim 44, wherein the spherical bearing surface of the annular air bearing member is convex.

46. The apparatus of claim 44, wherein the spherical bearing surface of the annular air bearing member is concave.

47. The apparatus of claim 44, wherein the bearing surface of the vertical support member mates with the spherical bearing surface of the annular air bearing member.

48. The apparatus of claim 44, wherein the bearing surface of the vertical support member mates with the planar bearing surface of the annular air bearing member.

49. The apparatus of claim 44, wherein the pressurized gas is negative pressure relative to ambient.

50. The apparatus of claim 44, wherein the pressurized gas is positive relative to ambient.

51. The apparatus of claim 44, wherein the armature coil is rigidly connected to the main frame.

52. The apparatus of claim 44, wherein the armature coil is rigidly connected to the object.

53. The apparatus of claim 44, wherein the object is below the apparatus.

54. The apparatus of claim 44, wherein the object is above the apparatus.

55. An apparatus for supporting and positioning an object comprising:
at least one air bearing member;
a flexure;
a vertical support member;
a main frame guiding the motion of the vertical support member;
a housing for pressurized gas;
wherein when the housing is filled with pressurized gas, a pressure differential acts on an area of the vertical support member to provide a desired force on an object; and
a voice coil motor comprising a mover and a stator, wherein the mover is connected to either the flexure and the vertical support member or to the flexure and the air bearing member.

56. The apparatus of claim 55, wherein the flexure comprises a first section able to bend about one of the X and Y axes and a second section able to bend about the other of the X and Y axes.

57. The apparatus of claim 55, wherein the flexure comprises a section able to bend about the X and Y axes.

58. The apparatus of claim 55, wherein the housing comprises rigid walls and an opening adapted to permit at least a portion of the vertical support member to enter the housing.

59. The apparatus of claim 58, wherein the opening in the housing is in a bottom rigid wall.

60. The apparatus of claim 55, wherein the pressurized gas is negatively pressurized relative to ambient.

61. The apparatus of claim 55, wherein the housing comprises an air bellows mechanically connected to the vertical support member.

62. The apparatus of claim 55, wherein the pressurized gas is positively pressurized relative to ambient.

63. The apparatus of claim 55, wherein the housing contains a substantially constant amount of pressurized fluid.

64. The apparatus of claim 55, wherein the housing contains fluid at a substantially constant pressure.

65. The apparatus of claim 55, wherein the mover is connected to the flexure and the vertical support.

66. The apparatus of claim 55, wherein the mover is connected to the air bearing member and the flexure.

67. The apparatus of claim 55, wherein the object is above the apparatus.

68. The apparatus of claim 55, wherein the object is below the apparatus.

69. The apparatus of claim 55, wherein the main frame comprises a vertical bushing to guide the motion of the vertical support member.

70. The apparatus of claim 55 further comprising:
an air bearing housing surrounding the air bearing member, and
wherein the air bearing housing reduces the volume of gas escaping to the surrounding environment.

71. An apparatus for supporting and positioning a fine stage in the “z” direction in a vacuum environment comprising:
an air bearing housing rigidly connected to the fine stage;
an air bearing member disposed within the air bearing housing and creating at least one air bearing when supplied with pressurized fluid;
wherein the air bearing housing limits the pressurized fluid escaping to the vacuum environment;
a flexure connected to the air bearing member;
a vertical support member connected to the flexure and journaled with an air bushing;
a main frame comprising the air bushing and adapted to remove pressurized fluid from the air bushing by pathways connected to a vacuum pump; and
a housing for pressurized gas;
wherein when the housing is filled with pressurized gas, a pressure differential acts on an area of the vertical support member to provide a desired force on the fine stage; and
a voice coil motor comprising a mover and a stator, wherein the mover is connected to the air bearing housing.

72. A system for supporting and positioning a fine stage in the three vertical degrees of freedom comprising:
a first Z support and positioning device supporting a fine stage at a first point;
a second Z support and positioning device supporting the fine stage at a second point;
a third Z support and positioning device supporting the fine stage a third point, and
a controller receiving target Z positions for at least one of the first, second, and third Z support and positioning devices and transmitting signals to the at least one positioning device on to precisely position the fine stage at particular Z position and orientation;
wherein the first, second, and third points are non-linear and at least one of the first, second, and third support and positioning devices comprises an apparatus of one of claims 1, 17, 27, 44, 55, and 71.

73. A system for isolating an object from vibration comprising:
a first Z support device supporting the object at a first point;
a second Z support device supporting the object at a second point; and
a third Z support device supporting the object a third point, wherein at least one of the Z support devices comprises an apparatus of one of claims 1 and 17 and the object weighs between about 10 kg and about 10,000 kg.

74. An exposure apparatus comprising the apparatus of one of claims 1, 17, 27, 44, 55, 71, and 72.

75. A method for manufacturing a device, the method comprising:
providing a substrate; and
forming an image on the substrate with the exposure apparatus of claim 74.

76. A method for forming an image on a wafer, the method comprising:
providing the wafer; and
forming an image on the wafer with the exposure apparatus of claim 74.
